(19) United States
(12) Patent Application Publication
(10) Pub. No.: US 2025/0201760 A1
(43) Pub. Date: Jun. 19, 2025

(54) HYBRID BONDING INSULATION MEMBRANE FORMING MATERIAL, METHOD OF PRODUCING SEMICONDUCTOR DEVICE AND SEMICONDUCTOR DEVICE

(71) Applicant: HD MICROSYSTEMS, LTD., Tokyo (JP)

(72) Inventors: Kenya ADACHI, Tokyo (JP); Satoshi YONEDA, Tokyo (JP); Kaori KOBAYASHI, Tokyo (JP); Daisaku MATSUKAWA, Tokyo (JP)

(21) Appl. No.: 18/849,939

(22) PCT Filed: Jan. 27, 2023
(86) PCT No.: PCT/JP2023/002759

§ 371 Date: Sep. 23, 2024

(30) Foreign Application Priority Data
Mar. 25, 2022 (JP) 2022-050451

(51) Int. Cl. H01L 23/00; C09J 5/04; C09J 7/38

(52) U.S. Cl. CPC H01L 24/80; C09J 5/04; C09J 7/38; C09J 2203/326; C09J 2301/414; C09J 2301/416; H01L 24/08; H01L 2224/08225; H01L 2224/80379; H01L 2224/80895; H01L 2224/80896

(57) ABSTRACT

A hybrid bonding insulating membrane forming material includes: a (A) polyimide precursor having a polymerizable unsaturated bonding site; a (B) solvent; and a (C) oxime-based photopolymerization initiator.

### TECHNICAL FIELD

The present disclosure relates to a hybrid bonding insulating membrane forming material, a method of producing a semiconductor device, and a semiconductor device.

### BACKGROUND ART

In recent years, three-dimensional mounting of semiconductor chips has been considered to improve the integration of LSIs (Large Scale Integrated Circuits). Non-Patent Document 1 discloses an example of three-dimensional mounting of semiconductor chips.

In a case in which three-dimensional mounting of semiconductor chips is performed by C2 W (Chip-to-Wafer) bonding, the use of hybrid bonding technology used in W2 W (Wafer-to-Wafer) bonding is being considered to perform fine bonding of wiring between devices.

In C2 W hybrid bonding, the heat generated during bonding can cause the substrate and chip to thermally expand, which may lead to misalignment. In order to solve this issue, Patent Document 1 discloses an example of a technology in which a cyclic olefin resin is used to lower the bonding temperature.

### RELATED ART DOCUMENTS

### Patent Documents

Patent Document 1: Japanese Patent Application Laid-Open (JP-A) No. 2019-204818

### Non Patent Documents

Non Patent Document 1: F. C. Chen et al., “System on Integrated Chips (SoIC TM) for 3D Heterogeneous Integration”,2019 IEEE 69th Electronic Components and Technology Conference (ECTC), p.594-599 (2019)

### SUMMARY OF INVENTION

In the method of C2 W bonding using hybrid bonding technology, a practical application of a method using inorganic materials such as silicon dioxide (SiO₂) for an insulating membrane is being considered. However, since inorganic materials are hard materials, for example, foreign matter derived from inorganic materials that is generated when cutting semiconductor chips into individual chips may adhere to a surface of the insulating film, thereby causing large voids at a joint interface. As a result, a yield of semiconductor device manufacturing is likely to decrease, or manufacturing costs is likely to increase because equipment such as a clean room with high cleanliness is required to remove foreign matter.

On the other hand, a method of C2 W bonding using hybrid bonding technology using an organic insulating membrane is still in the investigation stage and has not yet been put to practical use. In a case in which the cyclic olefin resin described in Patent Document 1 is used, a heat resistance of the resulting organic insulating membrane is insufficient. In a case in which the heat resistance of the organic insulating membrane is low, for example, voids may occur at a joint interface when exposed to high temperatures during C2 W bonding and subsequent annealing, causing joint failure.

In addition, in a case in which a method is adopted in which plural pillars made of a metal such as copper (Cu) are formed after joining, a photolithography process is used to remove the insulating membrane in the areas where the pillars are to be formed. From the viewpoint of manufacturing costs or the like, it is desirable for the organic insulating membrane to have high exposure sensitivity.

The present disclosure has been made in consideration of the above, and aims to provide a hybrid bonding insulating membrane forming material that has excellent exposure sensitivity and is capable of suppressing the occurrence of voids during joining, a method of producing a semiconductor device, and a semiconductor device.

### Solution to Problem

Means for solving the above problems include the following embodiments.
<1> A hybrid bonding insulating membrane forming material including a (A) polyimide precursor having a polymerizable unsaturated bonding site, a (B) solvent, and a (C) oxime-based photopolymerization initiator.
<2> The hybrid bonding insulating membrane forming material according to <1>, in which the (C) oxime-based photopolymerization initiator includes a compound represented by the following Formula (I):

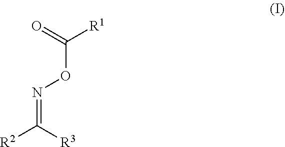

in which, in Formula (I), R¹ represents an alkyl group, an alkoxy group, a phenyl group, or a phenoxy group, R² represents an alkyl group, and R³ represents a carbonyl group or a monovalent organic group linked by a single bond.
<3> The hybrid bonding insulating membrane forming material according to <2>, in which the (C) oxime-based photopolymerization initiator includes a compound in which R¹ in Formula (I) is represented by an alkoxy group.
<4> The hybrid bonding insulating membrane forming material according to <2> or <3>, in which the (C) oxime-based photopolymerization initiator includes a compound A in which R¹ in Formula (I) is represented by an alkoxy group, and a compound B in which R¹ in Formula (I) is represented by an alkyl group or a phenyl group.
<5> The hybrid bonding insulating membrane forming material according to any one of <1> to <4>, in which the (A) polyimide precursor includes a compound having a structural unit represented by the following Formula (1):

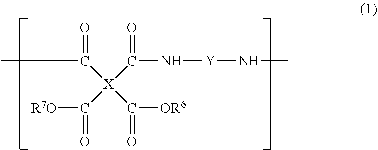

in which, in Formula (1), X represents a tetravalent organic group, Y represents a divalent organic group, and each of R⁶ and R⁷ independently represents a hydrogen atom or a monovalent organic group, and at least one of R⁶ or R⁷ has a polymerizable unsaturated bond.
<6> The hybrid bonding insulating membrane forming material according to <5>, in which the tetravalent organic group represented by X in Formula (1) is a group represented by the following Formula (E):

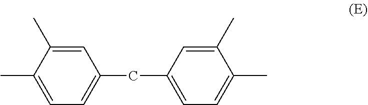

in which, in Formula (E), C represents a single bond, an alkylene group, a halogenated alkylene group, a carbonyl group, a sulfonyl group, an ether bond (—O—), a sulfide bond (—S—), a phenylene group, an ester bond (—O—C(═O)—), a silylene bond (—Si(R^{A})₂—) in which each of the two R^{A}s independently represents a hydrogen atom, an alkyl group, or a phenyl group), a siloxane bond (—O—(Si(R^{B})₂—O—)n) in which each of the two R^{B}s independently represents a hydrogen atom, an alkyl group, or a phenyl group, and n represents an integer of 1 or more), or a divalent group combining at least two of these.
<7> The hybrid bonding insulating membrane forming material according to <5> or <6>, in which the divalent organic group represented by Y in Formula (1) is a group represented by the following Formula (H):

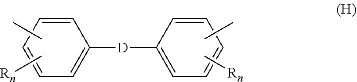

in which, in Formula (H), each R independently represents an alkyl group, an alkoxy group, a halogenated alkyl group, a phenyl group, or a halogen atom, and each n independently represents an integer from 0 to 4. D represents a single bond, an alkylene group, a halogenated alkylene group, a carbonyl group, a sulfonyl group, an ether bond (—O—), a sulfide bond (—S—), a phenylene group, an ester bond (—O—C(═O)—), a silylene bond (—Si(R^{A})₂—) in which each of two RAs independently represents a hydrogen atom, an alkyl group, or a phenyl group), a siloxane bond (—O—(Si(R^{B})₂—O—)ₙ) in which each of two R^{B}s independently represents a hydrogen atom, an alkyl group, or a phenyl group, and n represents an integer of 1 or more), or a divalent group combining at least two of these.
<8> The hybrid bonding insulating membrane forming material according to <7>, in which D in Formula (H) includes an ether bond (—O—).
<9> The hybrid bonding insulating membrane forming material according to any one of <5> to <8>, in which the monovalent organic group represented by R⁶ and R⁷in Formula (1) is a group represented by the following Formula (2), an ethyl group, an isobutyl group or a t-butyl group, and at least one of R⁶ or R⁷ is the group represented by Formula (2):

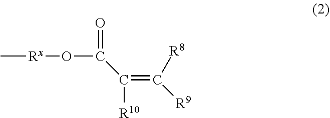

in which, in Formula (2), each of R⁸ to R¹⁰ independently represents a hydrogen atom or an aliphatic hydrocarbon group having 1 to 3 carbon atoms, and R^{x} represents a divalent linking group.
<10> The hybrid bonding insulating membrane forming material according to any one of <1> to <9>, further including (D) a sensitizer.
<11> The hybrid bonding insulating membrane forming material according to any one of <1> to <10>, further including (E) a polymerizable monomer.
<12> The hybrid bonding insulating membrane forming material according to any one of <1> to <11>, which has a glass transition temperature of from 50° C. to 300° C. in a case in which a cured product is formed.
<13> A method of producing a semiconductor device, the method including:
   preparing a first semiconductor substrate having a first substrate body, and a first electrode and a first organic insulating membrane provided on one surface of the first substrate body;
   preparing a semiconductor chip having a semiconductor chip substrate body, and a second organic insulating membrane and a second electrode provided on one surface of the semiconductor chip substrate body; and
   joining the first electrode to the second electrode, and bonding the first organic insulating membrane to the second organic insulating membrane,
   in which the hybrid bonding insulating membrane forming material according to any one of <1> to <12> is used in production of at least one of the first organic insulating membrane or the second organic insulating membrane.
<14> The method of producing a semiconductor device according to <13>, in which joining the first electrode to the second electrode is performed after bonding the first organic insulating membrane to the second organic insulating membrane.
<15> The method of producing a semiconductor device according to <13> or <14>, further including:
   polishing at least one of the one surface of the first semiconductor substrate or the one surface of the semiconductor chip before the first electrode is joined to the second electrode and before the first organic insulating membrane is bonded to the second organic insulating membrane.
<16> The method of producing a semiconductor device according to <15>, in which the polishing includes chemical mechanical polishing.
<17> The method of producing a semiconductor device according to <16>, in which the polishing further includes mechanical polishing.
<18> The method of producing a semiconductor device according to any one of <13> to <17>, in which, in the joining between the first electrode and the second electrode, at least one of the following is satisfied: a thickness of the first organic insulating film is greater than a thickness of the first electrode; or a thickness of the second organic insulating film is greater than a thickness of the second electrode.
<19> A semiconductor device including:
   a first semiconductor substrate having a first substrate body, and a first organic insulating membrane and a first electrode provided on one surface of the first substrate body; and
   a semiconductor chip having a semiconductor chip substrate body, and a second organic insulating membrane and a second electrode provided on one surface of the semiconductor chip substrate body,
   in which the first organic insulating membrane and the second organic insulating membrane are bonded to each other, and the first electrode and the second electrode are joined to each other, and
   at least one of the first organic insulating membrane or the second organic insulating membrane is a cured product of the hybrid bonding insulating membrane forming material according to any one of <1> to <12>.

### Advantageous Effects of Invention

In the present disclosure, it is possible to provide a hybrid bonding insulating membrane forming material that has excellent exposure sensitivity and is capable of suppressing the occurrence of voids during joining, a method of producing a semiconductor device, and a semiconductor device.

### BRIEF DESCRIPTION OF DRAWINGS

FIG. 1 is a cross-sectional view showing an example of a semiconductor device produced by a method of producing a semiconductor device according to one embodiment.

FIG. 2 is a diagram showing in sequence a method of producing a semiconductor device shown in FIG. 1.

FIG. 3 is a diagram showing in more detail a joining method in a method of producing a semiconductor device shown in FIG. 2.

FIG. 4 is a diagram showing a method of producing the semiconductor device shown in FIG. 1, and showing in sequence the processes following the process shown in FIG. 2 in sequence.

FIG. 5 is a diagram showing an example of applying a method of producing a semiconductor device according to one embodiment to Chip-to-Wafer (C2 W).

### DESCRIPTION OF EMBODIMENTS

Hereinafter, embodiments in the present invention will be described in detail. However, the present invention is not limited to the following embodiments. In the following embodiments, the components (including element steps, or the like.) are not essential unless otherwise specified. The same applies to the numerical values and their ranges, and they do not limit the present invention.

In the present disclosure, the term “process” includes not only a process independent of other processes, but also a process that cannot be clearly distinguished from other processes, as long as the purpose of the process is achieved.

In the present specification, in a case in which a numerical range is indicated using “to”, the numerical values before and after “to” are included as the minimum and maximum values, respectively.

In the present invention, in the numerical ranges described in stepwise, the upper limit or lower limit value described in a certain numerical range can also be replaced with the upper limit or lower limit value of another numerical range described in stepwise. In the numerical ranges described in the present disclosure, the upper or lower limit value of the numerical range may be replaced by the value shown in each example.

In the present disclosure, each component may contain two or more types of corresponding substances. In a case in which a composition contains two or more substances corresponding to each component, a content or amount of each component means a total content or amount of the two or more substances present in the composition, unless otherwise specified.

In the present disclosure, the terms “layer” and “film” include cases where the layer or film is formed over the entire area when the area is observed, as well as cases where the layer or film is formed only in a part of the area.

In the present disclosure, a thickness of a layer or film is determined by measuring the thicknesses of five points on the target layer or film and taking an arithmetic average value of the measured values.

A thickness of a layer or film may be measured using a micrometer or the like. In the present disclosure, in a case in which a thickness of a layer or film can be measured directly, it is measured using a micrometer. On the other hand, in a case in which a thickness of one layer or a total thickness of plural layers is measured, it may be measured by observing a cross section of the target using an electron microscope.

In the present disclosure, “(meth)acrylic group” means “acrylic group” and “methacrylic group”, “(meth)acrylate” means “acrylate” and “methacrylate”, and “(meth)acryloyl” means “acryloyl” and “methacryloyl”.

In the present disclosure, in a case in which a functional group has a substituent, a number of carbon atoms in the functional group means a total number of carbon atoms including a number of carbon atoms in the substituent.

In a case in which embodiments are described in the present disclosure with reference to figures, a configuration of the embodiment is not limited to a configuration shown in the figures. Furthermore, a sizes of the components in each figure are conceptual, and the relative relationships in size between the components are not limited to those shown in figures.

### <Hybrid Bonding Insulating Membrane Forming Material>

A hybrid bonding insulating membrane forming material in the present disclosure includes (A) a polyimide precursor having a polymerizable unsaturated bonding site, (B) a solvent, and (C) an oxime-based photopolymerization initiator. Hereinafter, the hybrid bonding insulating membrane forming material in the present disclosure is also referred to as the “insulating membrane forming material,” and the (A) polyimide precursor having a polymerizable unsaturated bonding site is also referred to as the “(A) polyimide precursor.” In addition, the “oxime-based” in the present disclosure includes a structure in which H of OH in the oxime structure: >C═N—OH is substituted.

The hybrid bonding insulating membrane forming material in the present disclosure has excellent exposure sensitivity and suppresses a occurrence of voids during joining. The reason for this is not clear, but can be considered as follows.

The (C) oxime-based photopolymerization initiator has a longer wavelength absorption than other photopolymerization initiators, and therefore has a high exposure sensitivity to the (A) polyimide precursor in the present disclosure. In addition, since the (C) oxime-based photopolymerization initiator has a high 5% thermal weight loss temperature, volatilization during heating for joining or the like is suppressed, and an occurrence of voids is suppressed.

Components contained in the insulating membrane forming material in the present disclosure and Components that may be contained therein are described below.

### ((A) Polyimide Precursor)

An insulating membrane forming material of in present disclosure includes a (A) polyimide precursor having a polymerizable unsaturated bonding site.

(A) Polyimide precursor is preferably at least one resin selected from the group consisting of polyamic acid, polyamic acid ester, polyamic acid salt, and polyamic acid amide. Polyamic acid ester and polyamic acid amide are compounds in which the hydrogen atoms of at least some of the carboxyl groups in a polyamic acid are substituted with monovalent organic groups, and polyamic acid salt is a compound in which at least some of the carboxyl groups in a polyamic acid form a salt structure with a basic compound having a pH of over 7.

(A) Polyimide precursor preferably includes a compound having a structural unit represented by the following Formula (1). This tends to result in a semiconductor device having an insulating membrane that exhibits high reliability.

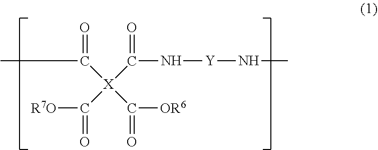

In Formula (1), X represents a tetravalent organic group, and Y represents a divalent organic group. Each of R⁶ and R⁷ independently represents a hydrogen atom or a monovalent organic group, and at least one of R⁶ or R⁷ has a polymerizable unsaturated bond. The polyimide precursor may have plural structural units represented by the above Formula (1), and Xs, Ys, R⁶s, and R⁷s in plural structural units may be the same or different. A combination of R⁶ and R⁷ is not particularly limited as long as each of them is independently a hydrogen atom or a monovalent organic group. For example, at least one of R⁶ or R⁷ may be a hydrogen atom, and the remaining may be a monovalent organic group described below, or they may all be the same or different monovalent organic groups. As described above, in a case in which the polyimide precursor has plural structural units represented by the above Formula (1), a combination of R⁶ and R⁷ in each structural unit may be the same or different.

In Formula (1), the tetravalent organic group represented by X preferably has 4 to 30 carbon atoms, more preferably 4 to 25 carbon atoms, even more preferably 5 to 13 carbon atoms, and particularly preferably 6 to 12 carbon atoms. The tetravalent organic group represented by X may contain an aromatic ring. Examples of the aromatic ring include aromatic hydrocarbon groups (for example, a number of carbon atoms constituting the aromatic ring is 6 to 20) and aromatic heterocyclic groups (for example, a number of atoms constituting the heterocyclic ring is 5 to 20). The tetravalent organic group represented by X is preferably an aromatic hydrocarbon group. Examples of the aromatic hydrocarbon group include a benzene ring, a naphthalene ring, and a phenanthrene ring.

In a case in which the tetravalent organic group represented by X contains an aromatic ring, each aromatic ring may have a substituent or may be unsubstituted. Examples of the substituent of the aromatic ring include an alkyl group, a fluorine atom, a halogenated alkyl group, a hydroxyl group, and an amino group. In a case in which the tetravalent organic group represented by X contains a benzene ring, the tetravalent organic group represented by X preferably contains one to four benzene rings, more preferably one to three benzene rings, and even more preferably one or two benzene rings.

In a case in which the tetravalent organic group represented by X contains two or more benzene rings, the benzene rings may be linked by a single bond, or may be linked by a linking group such as an alkylene group, a halogenated alkylene group, a carbonyl group, a sulfonyl group, an ether bond (—O—), a sulfide bond (—S—), a silylene bond (—Si(R^{A})₂—) in which each of two RAs independently represents a hydrogen atom, an alkyl group, or a phenyl group), a siloxane bond (—O—(Si(R^{B})₂—O—)ₙ) in which each of two R^{B}s independently represents a hydrogen atom, an alkyl group, or a phenyl group, and n is an integer of 1 or more), or a composite linking group combining at least two of these linking groups. In addition, two benzene rings may be bonded at two positions by at least one of a single bond or a linking group to form a five- or six-membered ring containing a linking group between the two benzene rings.

In Formula (1), the —COOR⁶ group and the —CONH— group are preferably in the ortho position relative to each other, and the —COOR⁷ group and the —CO— group are preferably in the ortho position relative to each other.

Specific examples of the tetravalent organic group represented by X include groups represented by the following Formulae (A) to (F). Among these, from the viewpoint of obtaining an insulating membrane that is excellent in flexibility and in which an occurrence of voids at a joint interface is further suppressed, a group represented by the following Formula (E) is preferred, and C in the following Formula (E) is more preferably a group containing an ether bond, and even more preferably an ether bond. The following Formula (F) is a structure in which C in the following Formula (E) is a single bond.

Note that the present disclosure is not limited to the following specific examples.

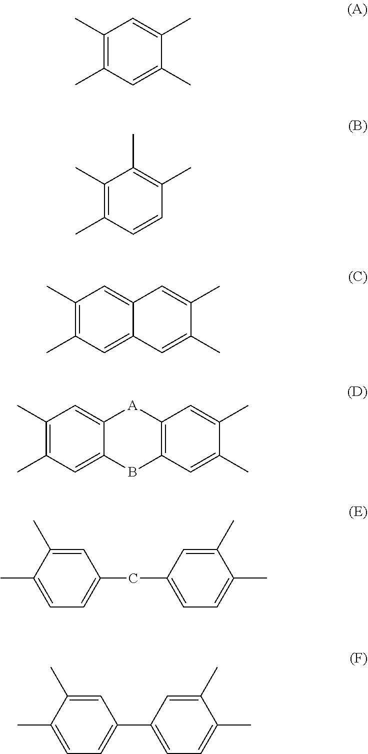

In Formula (D), each of A and B is independently a single bond or a divalent group that is not conjugated with a benzene ring. However, A and B cannot both be single bonds. Examples of the divalent group that is not conjugated with a benzene ring include a methylene group, a halogenated methylene group, a halogenated methylmethylene group, a carbonyl group, a sulfonyl group, an ether bond (—O—), a sulfide bond (—S—), and a silylene bond (—Si(R^{A})₂—) in which each of the two RAs independently represents a hydrogen atom, an alkyl group, or a phenyl group). Among these, each of A and B is independently preferably a methylene group, a bis(trifluoromethyl)methylene group, a difluoromethylene group, an ether bond, a sulfide bond or the like, and more preferably an ether bond.

In Formula (E), C represents a single bond, an alkylene group, a halogenated alkylene group, a carbonyl group, a sulfonyl group, an ether bond (—O—), a sulfide bond (—S—), a phenylene group, an ester bond (—O—C(═O)—), a silylene bond (—Si(R^{A})₂—) in which each of the two RAs independently represents a hydrogen atom, an alkyl group, or a phenyl group), a siloxane bond (—O—(Si(R^{B})₂—O—)ₙ) in which each of the two R^{B}s independently represents a hydrogen atom, an alkyl group, or a phenyl group, and n represents an integer of 1 or more), or a divalent group combining at least two of these. C preferably contains an ether bond, and is more preferably an ether bond.

C may include a structure represented by the following Formula (C1).

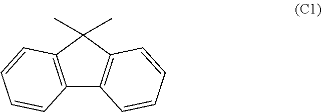

The alkylene group represented by C in Formula (E) is preferably an alkylene group having 1 to 10 carbon atoms, more preferably an alkylene group having 1 to 5 carbon atoms, and even more preferably an alkylene group having 1 or 2 carbon atoms. Specific examples of the alkylene group represented by C in Formula (E) include linear an alkylene group such as methylene group, ethylene group, trimethylene group, tetramethylene group, pentamethylene group, and hexamethylene group; a branched alkylene group such as a methylmethylene group, a methylethylene group, an ethylmethylene group, a dimethylmethylene group, a 1,1-dimethylethylene group, a 1-methyltrimethylene group, a 2-methyltrimethylene group, an ethylethylene group, a 1-methyltetramethylene group, a 2-methyltetramethylene group, a 1-ethyltrimethylene group, a 2-ethyltrimethylene group, a 1,1-dimethylethylene group, a 1,2-dimethyltrimethylene group, a 2,2-dimethyltrimethylene group, a 1-methylpentamethylene group, a 2-methylpentamethylene group, a 3-methylpentamethylene group, a 1-ethyltetramethylene group, a 2-ethyltetramethylene group, a 1,1-dimethyltetramethylene group, a 1,2-dimethyltetramethylene group, a 2,2-dimethyltetramethylene group, a 1,3-dimethyltetramethylene group, a 2,3-dimethyltetramethylene group, and a 1,4-dimethyltetramethylene group. Among these, a methylene group is preferred.

The halogenated alkylene group represented by C in Formula (E) is preferably a halogenated alkylene group having 1 to 10 carbon atoms, more preferably a halogenated alkylene group having 1 to 5 carbon atoms, and even more preferably a halogenated alkylene group having 1 to 3 carbon atoms.

Specific examples of the halogenated alkylene group represented by C in Formula (E) include an alkylene group in which at least one hydrogen atom contained in the alkylene group represented by C in Formula (E) is replaced with a halogen atom such as a fluorine atom or a chlorine atom. Among these, a fluoromethylene group, a difluoromethylene group and a hexafluorodimethylmethylene group are preferred.

The alkyl group represented by R^{A} or R^{B} contained in the silylene bond or siloxane bond is preferably an alkyl group having 1 to 5 carbon atoms, more preferably an alkyl group having 1 to 3 carbon atoms, and even more preferably an alkyl group having 1 or 2 carbon atoms. Specific examples of the alkyl group represented by R^{A} or R^{B} include a methyl group, an ethyl group, an n-propyl group, an isopropyl group, an n-butyl group, an isobutyl group, an s-butyl group, and a t-butyl group.

Specific examples of the tetravalent organic group represented by X may be groups represented by the following Formulae (J) to (O).

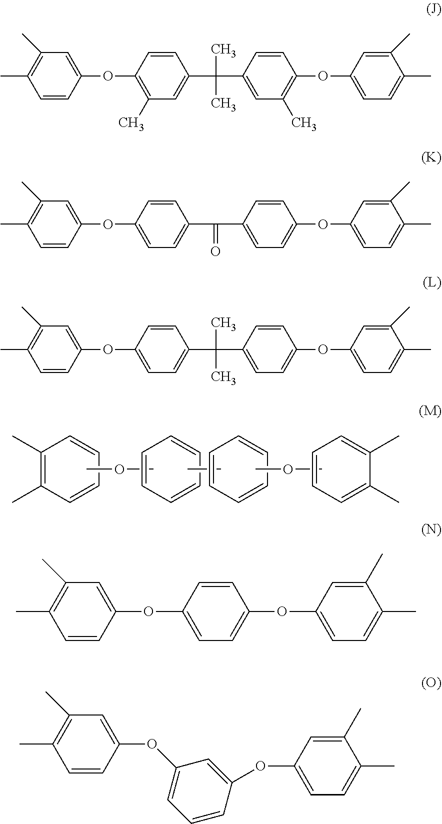

In Formula (1), the divalent organic group represented by Y preferably has 4 to 25 carbon atoms, more preferably 6 to 20 carbon atoms, and even more preferably 12 to 18 carbon atoms.

A main structure of the divalent organic group represented by Y may be the same as the main structure of the tetravalent organic group represented by X, and the preferred main structure of the divalent organic group represented by Y may be the same as the preferred main structure of the tetravalent organic group represented by X. The main structure of the divalent organic group represented by Y may be a structure in which two bonding positions of the tetravalent organic group represented by X are substituted with atoms (for example, hydrogen atoms) or functional groups (for example, alkyl groups).

The divalent organic group represented by Y may be a divalent aliphatic group or a divalent aromatic group. From the viewpoint of heat resistance, the divalent organic group represented by Y is preferably a divalent aromatic group. Examples of the divalent aromatic group include a divalent aromatic hydrocarbon group (for example, a number of carbon atoms constituting the aromatic ring is 6 to 20) and a divalent aromatic heterocyclic group (for example, the number of atoms constituting the heterocyclic ring is 5 to 20), with a divalent aromatic hydrocarbon group being preferred.

Specific examples of the divalent aromatic group represented by Y include groups represented by the following Formulae (G) and (H). Among these, from the viewpoint of obtaining an insulating membrane having excellent flexibility and in which an occurrence of voids at a joint interface is further suppressed, a group represented by the following Formula (H) is preferred, and among these, D in the following Formula (H) is more preferably a group containing a single bond or an ether bond, even more preferably a group containing a single bond or an ether bond, particularly preferably a group containing an ether bond, and is extremely preferably an ether bond.

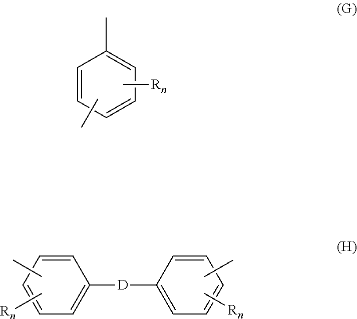

In Formulae (G) to (H), each R independently represents an alkyl group, an alkoxy group, a halogenated alkyl group, a phenyl group, or a halogen atom, and each n independently represents an integer from 0 to 4.

In Formula (H), D represents a single bond, an alkylene group, a halogenated alkylene group, a carbonyl group, a sulfonyl group, an ether bond (—O—), a sulfide bond (—S—), a phenylene group, an ester bond (—O—C(═O)—), a silylene bond (—Si(R^{A})₂—) in which each of the two RAs independently represents a hydrogen atom, an alkyl group, or a phenyl group), a siloxane bond (—O—(Si(R^{B})₂—O—)ₙ) in which each of the two R^{B}s independently represents a hydrogen atom, an alkyl group, or a phenyl group, and n is an integer of 1 or more), or a divalent group combining at least two of these. D may also be a structure represented by Formula (C1) above. Specific examples of D in Formula (H) are the same as the specific examples of C in Formula (E).

It is preferable that each D in Formula (H) is independently a single bond, an ether bond, a group containing an ether bond and a phenylene group, a group containing an ether bond, a phenylene group and an alkylene group, or the like.

The alkyl group represented by R in Formulae (G) to (H) is preferably an alkyl group having 1 to 10 carbon atoms, more preferably an alkyl group having 1 to 5 carbon atoms, and even more preferably an alkyl group having 1 or 2 carbon atoms.

Specific examples of the alkyl group represented by R in Formulae (G) to (H) include a methyl group, an ethyl group, an n-propyl group, an isopropyl group, an n-butyl group, an isobutyl group, an s-butyl group, and a t-butyl group.

The alkoxy group represented by R in Formulae (G) to (H) is preferably an alkoxy group having 1 to 10 carbon atoms, more preferably an alkoxy group having 1 to 5 carbon atoms, and even more preferably an alkoxy group having 1 or 2 carbon atoms.

Specific examples of the alkoxy group represented by R in Formulae (G) to (H) include a methoxy group, an ethoxy group, an n-propoxy group, an isopropoxy group, an n-butoxy group, an isobutoxy group, an s-butoxy group, and a t-butoxy group.

The halogenated alkyl group represented by R in Formulae (G) to (H) is preferably a halogenated alkyl group having 1 to 5 carbon atoms, more preferably a halogenated alkyl group having 1 to 3 carbon atoms, and even more preferably a halogenated alkyl group having 1 or 2 carbon atoms.

Specific examples of halogenated alkyl groups represented by R in Formulae (G) to (H) include an alkyl group in which at least one hydrogen atom contained in the alkyl group represented by R in Formulae (G) to (H) is substituted with a halogen atom such as a fluorine atom or a chlorine atom. Among these, a fluoromethyl group, a difluoromethyl group, a trifluoromethyl group or the like are preferred.

In Formulae (G) to (H), n is preferably form 0 to 2, more preferably 0 or 1, and even more preferably 0.

Specific examples of the divalent aliphatic group represented by Y include a linear or branched alkylene group, a cycloalkylene group, and a divalent group having a polyalkylene oxide structure.

The linear or branched alkylene group represented by Y is preferably an alkylene group having from 1 to 20 carbon atoms, more preferably an alkylene group having from 1 to 15 carbon atoms, and even more preferably an alkylene group having from 1 to 10 carbon atoms.

Specific examples of alkylene groups represented by Y include a tetramethylene group, a hexamethylene group, a heptamethylene group, an octamethylene group, a nonamethylene group, a decamethylene group, an undecamethylene group, a dodecamethylene group, a 2-methylpentamethylene group, a 2-methylhexamethylene group, a 2-methylheptamethylene group, a 2-methyloctamethylene group, a 2-methylnonamethylene group, and a 2-methyldecamethylene group.

The cycloalkylene group represented by Y is preferably a cycloalkylene group having 3 to 10 carbon atoms, and more preferably a cycloalkylene group having 3 to 6 carbon atoms.

Specific examples of the cycloalkylene group represented by Y include a cyclopropylene group and a cyclohexylene group.

The unit structure contained in the divalent group having a polyalkylene oxide structure represented by Y is preferably an alkylene oxide structure having 1 to 10 carbon atoms, more preferably an alkylene oxide structure having 1 to 8 carbon atoms, and even more preferably an alkylene oxide structure having 1 to 4 carbon atoms. Among them, the polyalkylene oxide structure is preferably a polyethylene oxide structure or a polypropylene oxide structure. The alkylene group in the alkylene oxide structure may be linear or branched. The unit structure in the polyalkylene oxide structure may be one type or two or more types.

The divalent organic group represented by Y may be a divalent group having a polysiloxane structure. Examples of the divalent group having a polysiloxane structure represented by Y include a divalent group having a polysiloxane structure in which the silicon atom in the polysiloxane structure is bonded to a hydrogen atom, an alkyl group having 1 to 20 carbon atoms, or an aryl group having 6 to 18 carbon atoms.

Specific examples of the alkyl group having 1 to 20 carbon atoms bonded to the silicon atom in the polysiloxane structure include methyl, an ethyl group, an n-propyl group, an isopropyl group, an n-butyl group, a t-butyl group, an n-octyl group, a 2-ethylhexyl group, and an -dodecyl group group. Among these, a methyl group is preferred.

The aryl group having 6 to 18 carbon atoms bonded to the silicon atom in the polysiloxane structure may be unsubstituted or substituted. Specific examples of the substituent in a case in which the aryl group has a substituent include a halogen atom, an alkoxy group, and a hydroxy group. Specific examples of the aryl group having 6 to 18 carbon atoms include a phenyl group, a naphthyl group, and a benzyl group. Among these, a phenyl group is preferred.

The alkyl group having 1 to 20 carbon atoms or the aryl group having 6 to 18 carbon atoms in the polysiloxane structure may be of one type or of two or more types.

The silicon atom constituting the divalent group having a polysiloxane structure represented by Y may be bonded to the NH group in Formula (1) via an alkylene group such as a methylene group or an ethylene group, or an arylene group such as a phenylene group.

The group represented by Formula (G) is preferably a group represented by the following Formula (G′), and the group represented by Formula (H) is preferably a group represented by the following Formula (H′), Formula (H″) or Formula (H″). From the viewpoint of having a flexible structure and excellent joint properties, it is more preferably a group represented by the following Formula (H′) or Formula (H″).

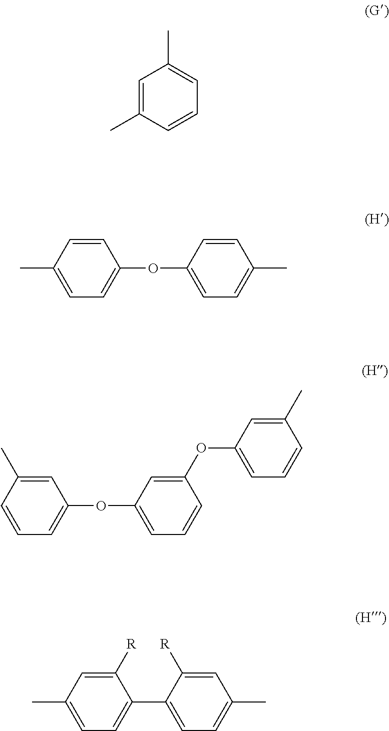

In Formula (H″), each R independently represents an alkyl group, an alkoxy group, a halogenated alkyl group, a phenyl group, or a halogen atom. R is preferably an alkyl group, and more preferably a methyl group.

In Formula (1), a combination of the tetravalent organic group represented by X and the divalent organic group represented by Y is not particularly limited. An example of the combination of the tetravalent organic group represented by X and the divalent organic group represented by Y is a combination in which X is a group represented by Formula (E) and Y is a group represented by Formula (H).

Each of R⁶ and R⁷ independently represents a hydrogen atom or a monovalent organic group, and at least one of R⁶ or R⁷ has a polymerizable unsaturated bond. The monovalent organic group is preferably an aliphatic hydrocarbon group having 1 to 4 carbon atoms or an organic group having an unsaturated double bond, more preferably any of a group represented by the following Formula (2), an ethyl group, an isobutyl group, or a t-butyl group, and even more preferably includes an aliphatic hydrocarbon group having 1 or 2 carbon atoms or a group represented by the following Formula (2). In this case, at least one of R⁶ or R⁷ is a group represented by Formula (2).

In a case in which the monovalent organic group includes an organic group having an unsaturated double bond, preferably a group represented by the following Formula (2), an i-ray transmittance is high, and an excellent cured product tends to be formed even when cured at a low temperature of 400° C. or less. In addition, in a case in which the monovalent organic group includes an organic group having an unsaturated double bond, preferably a group represented by the following Formula (2), at least a part of the unsaturated double bond portion is eliminated by the (C) compound.

Specific examples of the hydrocarbon group having 1 to 4 carbon atoms include a methyl group, an ethyl group, an n-propyl group, an isopropyl group, an n-butyl group and a t-butyl group, and among these, an ethyl group, an isobutyl group, and a t-butyl group are preferred.

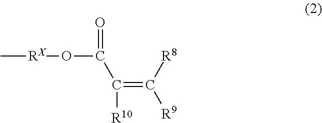

In Formula (2), each of R⁸ to R¹⁰ independently represents a hydrogen atom or an aliphatic hydrocarbon group having 1 to 3 carbon atoms, and R^{x} represents a divalent linking group.

The aliphatic hydrocarbon group represented by R⁸ to R¹⁰ in Formula (2) has 1 to 3 carbon atoms, preferably 1 or 2 carbon atoms. Specific examples of the aliphatic hydrocarbon group represented by R⁸ to R¹⁰ include a methyl group, an ethyl group, an n-propyl group, an isopropyl group, and a methyl group is preferred.

A preferred combination of R⁸ to R¹⁰ in Formula (2) is one in which R⁸ and R⁹ are hydrogen atoms, and R¹⁰ is a hydrogen atom or a methyl group.

R^{x} in Formula (2) is a divalent linking group, preferably a hydrocarbon group having 1 to 10 carbon atoms. Examples of the hydrocarbon group having 1 to 10 carbon atoms include linear or branched an alkylene group.

A number of carbon atoms in R^{x} is preferably 1 to 10, more preferably 2 to 5, and even more preferably 2 or 3.

In Formula (1), it is preferable that at least one of R⁶ or R⁷ is a group represented by Formula (2), and it is more preferable that both R⁶ and R⁷ are groups represented by Formula (2).

In a case in which (A) the polyimide precursor contains a compound having a structural unit represented by Formula (1), a ratio of the groups represented by Formula (2) as R⁶ and R⁷ to a total of R⁶ and R⁷ of all structural units contained in the compound is preferably 60 mol % or more, more preferably 70 mol % or more, and even more preferably 80 mol % or more. An upper limit of the above ratio is not particularly limited, and may be 100 mol %.

The above ratio may be 0 mol % or more and less than 60 mol %.

The group represented by Formula (2) is preferably a group represented by the following Formula (2′):

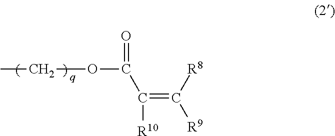

In Formula (2′), each of R⁸ to R¹⁰ independently represents a hydrogen atom or an aliphatic hydrocarbon group having 1 to 3 carbon atoms, and q represents an integer from 1 to 10.

In Formula (2′), q represents an integer from 1 to 10, preferably an integer from 2 to 5, and more preferably 2 or 3.

A content of the structural unit represented by the Formula (1) contained in the compound having the structural unit represented by the Formula (1) is preferably 60 mol % or more, more preferably 70 mol % or more, and even more preferably 80 mol % or more, with respect to a total structural units. An upper limit of the above content is not particularly limited, and may be 100 mol %.

(A) The polyimide precursor may be synthesized using a tetracarboxylic dianhydride and a diamine compound. In this case, in Formula (1), X corresponds to a residue derived from a tetracarboxylic dianhydride, and Y corresponds to a residue derived from a diamine compound. The (A) polyimide precursor may be synthesized using a tetracarboxylic acid instead of a tetracarboxylic dianhydride.

Specific examples of the tetracarboxylic dianhydride include pyromellitic dianhydride, 2,3,6,7-naphthalenetetracarboxylic dianhydride, 3,3′,4,4′-biphenyltetracarboxylic dianhydride, 3,3′,4,4′-biphenylethertetracarboxylic dianhydride, 3,3′,4,4′-benzophenonetetracarboxylic dianhydride, 1,2,5,6-naphthalenetetracarboxylic dianhydride, 2,3,5,6-pyridinetetracarboxylic dianhydride, 1,4,5,8-naphthalenetetracarboxylic dianhydride, 3,4,9,10-perylenetetracarboxylic dianhydride, m-terphenyl-3,3′,4,4′-tetracarboxylic dianhydride, p-terphenyl-3,3′,4,4′-tetracarboxylic dianhydride, 1,1,4,4′-(4,4′-isopropylidenediphenoxy)diphthalic anhydride, 1,3,3,3-hexafluoro-2,2-bis(2,3-dicarboxyphenyl) propane dianhydride, 1,1,1,3,3,3-hexafluoro-2,2-bis(3,4-dicarboxyphenyl) propane dianhydride, 2,2-bis(2,3-dicarboxyphenyl) propane dianhydride, 2,2-bis(3,4-dicarboxyphenyl) propane dianhydride, 2,2-bis {4′-(2,3-dicarboxyphenoxy)phenyl}propane dianhydride, 2,2-bis {4′-(3,4-dicarboxyphenoxy)phenyl}propane dianhydride, 1,1,1,3,3,3-hexafluoro-2,2-bis {4′-(2,3-dicarboxyphenoxy)phenyl}propane dianhydride, 1,1,1,3,3,3-hexafluoro-2,2-bis {4′-(3,4-dicarboxyphenoxy)phenyl}propane dianhydride, 4,4′-oxydiphthalic dianhydride, 4,4′-sulfonyldiphthalic dianhydride, 9,9-bis(3,4-dicarboxyphenyl) fluorene dianhydride, cyclopentanone bisspironorbornane tetracarboxylic dianhydride, and 2,2-bis {4-(4′-phenoxy)phenyl}propane tetracarboxylic dianhydride. Among these, 3,3′,4,4′-biphenyl ether tetracarboxylic dianhydride and 3,3′,4,4′-biphenyl tetracarboxylic dianhydride are preferred, and 3,3′,4,4′-biphenyl ether tetracarboxylic dianhydride is more preferred from the viewpoint of joining at lower temperatures.

Tetracarboxylic dianhydrides may be used singly or in combination of two or more kinds thereof.

Specific examples of the diamine compound include 2,2′-dimethylbiphenyl-4,4′-diamine, 2,2′-bis(trifluoromethyl)-4,4′-diaminobiphenyl, 2,2′-difluoro-4,4′-diaminobiphenyl, p-phenylenediamine, m-phenylenediamine, p-xylylenediamine, m-xylylenediamine, 1,5-diaminonaphthalene, benzidine, 4,4′-diaminodiphenyl ether, 3,4′-diaminodiphenyl ether, 3,3′-diaminodiphenyl ether, 2,4′-diaminodiphenyl ether, and 2,2′-diaminodiphenyl ether, 4,4′-diaminodiphenyl sulfone, 3,4′-diaminodiphenyl sulfone, 3,3′-diaminodiphenyl sulfone, 2,4′-diaminodiphenyl sulfone, 2,2′-diaminodiphenyl sulfone, 4,4′-diaminodiphenyl sulfide, 3,4′-diaminodiphenyl sulfide, 3,3′-diaminodiphenyl sulfide, 2,4′-diaminodiphenyl sulfide, 2,2′-diaminodiphenyl sulfide, o-tolidine, o-tolidine sulfone, 4,4′-methylenebis(2,6-diethylaniline), 4,4′-methylenebis(2,6-diisopropylaniline), 2,4-diaminomesitylene, 1,5-diaminonaphthalene, 4,4′-benzophenonediamine, bis-{4-(4′-aminophenoxy)phenyl}sulfone, 2,2-bis {4-(4′-aminophenoxy)phenyl}propane, 3,3′-dimethyl-4,4′-diaminodiphenylmethane, 3,3′, 5,5′-tetramethyl-4,4′-diaminodiphenylmethane, bis {4-(3′-aminophenoxy)phenyl}sulfone, 2,2-bis(4-aminophenyl) propane, 9,9-bis(4-aminophenyl) fluorene, 1,3-bis(3-aminophenoxy)benzene, 1,4-diaminobutane, 1,6-diaminohexane, 1,7-diaminoheptane, 1,8-diaminooctane, 1,9-diaminononane, 1,10-diaminodecane, 1,11-diaminoundecane, 1,12-diaminododecane, 2-methyl-1,5-diaminopentane, 2-methyl-1,6-diaminohexane, 2-methyl-1,7-diaminoheptane, 2-methyl-1,8-diaminooctane, 2-methyl-1,9-diaminononane, 2-methyl-1,10-diaminodecane, 1,4-cyclohexanediamine, 1,3-cyclohexanediamine, and diaminopolysiloxane. As the diamine compound, 2,2′-dimethylbiphenyl-4,4′-diamine, m-phenylenediamine, 4,4′-diaminodiphenyl ether and 1,3-bis(3-aminophenoxy)benzene are preferred. Among these, 4,4′-diaminodiphenyl ether, 1,3-bis(3-aminophenoxy)benzene and 2,2-bis {4-(4′-aminophenoxy)phenyl}propane are more preferred from the viewpoint of having a flexible structure and excellent adhesiveness.

The diamine compounds may be used singly or in combination of two or more kinds thereof.

The compound having a structural unit represented by Formula (1), in which at least one of R⁶ or R⁷ in Formula (1) is a monovalent organic group, can be obtained, for example, by the following method (a) or (b).
(a) A tetracarboxylic dianhydride (preferably a tetracarboxylic dianhydride represented by the following Formula (8)) is reacted with a compound represented by R—OH in an organic solvent to obtain a diester derivative, and then the diester derivative is subjected to a condensation reaction with a diamine compound represented by H₂N—Y—NH₂.
(b) A tetracarboxylic dianhydride is reacted with a diamine compound represented by H₂N—Y—NH₂ in an organic solvent to obtain a polyamic acid solution, and a compound represented by R—OH is added to the polyamic acid solution and reacted in the organic solvent to introduce an ester group.

Here, Y in the diamine compound represented by H₂N—Y—NH₂ is the same as Y in Formula (1), and specific examples and preferred examples are also the same. Furthermore, R in the compound represented by R—OH represents a monovalent organic group, and specific and preferred examples are the same as those of R⁶ and R⁷ in Formula (1).

The tetracarboxylic dianhydride represented by Formula (8), the diamine compound represented by H₂N—Y—NH₂, and the compound represented by R—OH may each be used singly or in combination of two or more kinds thereof.

Examples of the aforementioned organic solvents include N-methyl-2-pyrrolidone, y-butyrolactone, dimethoxyimidazolidinone, and 3-methoxy-N,N-dimethylpropanamide, and among these, 3-methoxy-N,N-dimethylpropanamide is preferred.

A polyimide precursor may be synthesized by allowing a dehydration condensation agent to act on the polyamic acid solution together with the compound represented by R—OH. The dehydration condensation agent preferably includes at least one selected from the group consisting of trifluoroacetic anhydride, N,N′-dicyclohexylcarbodiimide (DCC), and 1,3-diisopropylcarbodiimide (DIC).

The aforementioned compound contained in the (A) polyimide precursor may be obtained by reacting a tetracarboxylic dianhydride represented by the following Formula (8) with a compound represented by R—OH to form a diester derivative, then converting it to an acid chloride by reacting it with a chlorinating agent such as thionyl chloride, and then reacting the acid chloride with a diamine compound represented by H₂N—Y—NH₂.

The aforementioned compound contained in the (A) polyimide precursor may be obtained by reacting a tetracarboxylic dianhydride represented by the following Formula (8) with a compound represented by R—OH to form a diester derivative, and then reacting the diamine compound represented by H₂N—Y—NH₂ with the diester derivative in the presence of a carbodiimide compound.

The aforementioned compound contained in the (A) polyimide precursor can be obtained by reacting a tetracarboxylic dianhydride represented by the following Formula (8) with a diamine compound represented by H₂N—Y—NH₂ to form a polyamic acid, then isoimidizing the polyamic acid in the presence of a dehydrating condensing agent such as trifluoroacetic anhydride, and then reacting it with a compound represented by R—OH. Alternatively, a compound represented by R—OH may be allowed to act on a portion of the tetracarboxylic dianhydride in advance, and the partially esterified tetracarboxylic dianhydride may be reacted with a diamine compound represented by H₂N—Y—NH₂.

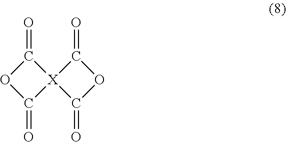

In Formula (8), X is the same as X in Formula (1), and specific examples and preferred examples are also the same.

The compound represented by R—OH used in the synthesis of the aforementioned compound contained in (A) polyimide precursor may be a compound in which a hydroxy group is bonded to RY of the group represented by Formula (2), or a compound in which a hydroxy group is bonded to the terminal methylene group of the group represented by Formula (2′). Specific examples of the compound represented by R—OH include methanol, ethanol, n-propanol, isopropanol, n-butanol, 2-hydroxyethyl methacrylate, 2-hydroxyethyl acrylate, 2-hydroxyethyl methacrylate, 2-hydroxypropyl acrylate, 2-hydroxypropyl methacrylate, 2-hydroxybutyl acrylate, 2-hydroxybutyl methacrylate, 4-hydroxybutyl acrylate, and 4-hydroxybutyl methacrylate, and among these, 2-hydroxyethyl methacrylate and 2-hydroxyethyl acrylate are preferred.

There is no particular restriction on a molecular weight of the (A) polyimide precursor. For example, the weight average molecular weight is preferably 10,000 to 200,000, and more preferably 10,000 to 100,000.

The weight average molecular weight may be measured, for example, by gel permeation chromatography, and may be calculated by conversion using a standard polystyrene calibration curve.

The insulating membrane forming material in the present disclosure may further contain a dicarboxylic acid, and the (A) polyimide precursor contained in the insulating membrane forming material may have a structure in which a part of the amino group in the (A) polyimide precursor reacts with a carboxy group in the dicarboxylic acid. For example, when synthesizing the polyimide precursor, a part of the amino group of the diamine compound may react with a carboxy group of the dicarboxylic acid.

The dicarboxylic acid may be a dicarboxylic acid having a (meth)acrylic group, for example, a dicarboxylic acid represented by the following Formula: In this case, when synthesizing the (A) polyimide precursor, a part of the amino groups of the diamine compound is reacted with a carboxy group of the dicarboxylic acid, so that a methacryl group derived from the dicarboxylic acid may be introduced into the (A) polyimide precursor.

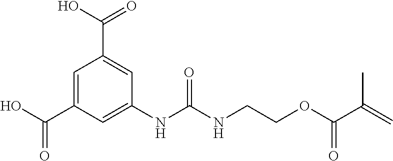 [SMILES: C=C(C)C(=O)OCCNC(=O)Nc1cc(C(=O)O)cc(C(=O)O)c1]

The insulating membrane forming material in the present disclosure may contain a polyimide resin in addition to the (A) polyimide precursor. By combining the polyimide precursor and the polyimide resin, it is possible to suppress a generation of volatile matter due to dehydration cyclization during imide ring formation, and therefore an occurrence of voids tends to be suppressed. The polyimide resin refers to a resin having an imide structure in all or part of the resin structure. It is preferable that the polyimide resin is soluble in the solvent of the insulating membrane forming material using the polyimide precursor.

The polyimide resin is not particularly limited as long as it is a polymeric compound having plural structural units including imide bonds, and it is preferable that it contains, for example, a compound having a structural unit represented by the following Formula (X). This tends to result in a semiconductor device having an insulating membrane that exhibits high reliability.

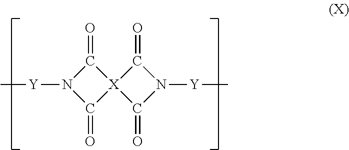

In Formula (X), X represents a tetravalent organic group, and Y represents a divalent organic group. Preferred examples of X and Y in Formula (X) are the same as the preferred examples of X and Y in Formula (1) described above.

In a case in which the insulating membrane forming material in the present disclosure contains a polyimide resin, a ratio of the polyimide resin to a total of the polyimide precursor and the polyimide resin may be from 15% by mass to 50% by mass, or from 10% by mass to 20% by mass.

The insulating membrane forming material in the present disclosure may contain other resins other than the polyimide precursor and the polyimide resin (A). Examples of the other resins include a novolac resin, an acrylic resin, a polyether nitrile resin, a polyether sulfone resin, an epoxy resin, a polyethylene terephthalate resin, a polyethylene naphthalate resin, a polyvinyl chloride resin from the viewpoint of heat resistance. The other resins may be used singly or in combination of two or more kinds thereof.

In the insulating membrane forming material in the present disclosure, a content of the (A) polyimide precursor with respect to a total amount of the resin components is preferably from 50% by mass to 100% by mass, more preferably from 70% by mass to 100% by mass, and even more preferably from 90% by mass to 100% by mass.

### ((B) Solvent)

The insulating membrane forming material in the present disclosure contains a (B) solvent (hereinafter also referred to as “(B) component”). The (B) component may be used singly or in combination of two or more kinds thereof. For example, from the viewpoint of reducing the reproductive toxicity and environmental load of the insulating membrane forming material, the (B) component preferably contains at least one selected from the group consisting of compounds represented by the following Formulae (3) to (8).

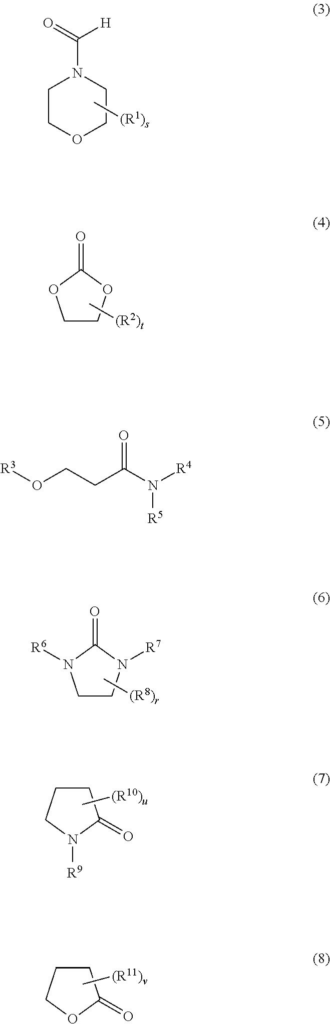

In Formulae (3) to (8), each of R¹, R², R⁸, R¹⁰, and R¹¹ is independently an alkyl group having 1 to 4 carbon atoms, and each of R³ to R⁷ and R⁹ is independently a hydrogen atom or an alkyl group having 1 to 4 carbon atoms. s is an integer from 0 to 8, t is an integer from 0 to 4, r is an integer from 0 to 4, and u and v are integers from 0 to 3.

In Formula (3), s is preferably 0.

In Formula (4), the alkyl group having 1 to 4 carbon atoms for R² is preferably a methyl group or an ethyl group. t is preferably 0, 1, or 2, and more preferably 1.

In Formula (5), the alkyl group having 1 to 4 carbon atoms for R³ is preferably a methyl group, an ethyl group, a propyl group, or a butyl group. The alkyl group having 1 to 4 carbon atoms for R⁴ and R⁵ is preferably a methyl group or an ethyl group.

In Formula (6), the alkyl groups having 1 to 4 carbon atoms for R⁶ to R⁸ are preferably a methyl group or an ethyl group. r is preferably 0 or 1, more preferably 0.

In Formula (7), the alkyl groups having 1 to 4 carbon atoms for R⁹ and R¹⁰ are preferably a methyl group or an ethyl group. u is preferably 0 or 1, more preferably 0.

In Formula (8), the alkyl group having 1 to 4 carbon atoms for R¹¹ is preferably a methyl group or an ethyl group. v is preferably 0 or 1, more preferably 0.

The component (B) may be, for example, at least one of a compound represented by Formulae (4), (5), (6), (7), or (8), or at least one of a compound represented by Formulae (5), (7), or (8).

Specific examples of the component (B) include the following compounds.

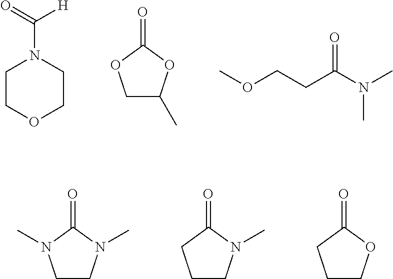

The component (B) contained in the insulating membrane forming material in the present disclosure is not limited to the above-mentioned compounds, and may be other solvents. The component (B) may be an ester solvent, an ether solvent, a ketone solvent, a hydrocarbon solvent, an aromatic hydrocarbon solvent, a sulfoxide solvent, or the like.

Examples of the ester solvent include ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, γ-butyrolactone, ε-caprolactone, σ-valerolactone, alkoxy alkyl acetates such as methyl alkoxy acetate, ethyl alkoxy acetate, and butyl alkoxy acetate (for example, methyl methoxy acetate, ethyl methoxy acetate, butyl methoxy acetate, methyl ethoxy acetate, and ethyl ethoxy acetate), 3-alkoxy propionic acid alkyl esters such as methyl 3-alkoxy propionate and ethyl 3-alkoxy propionate (for example, methyl 3-methoxy propionate, ethyl 3-methoxy propionate, methyl 3-ethoxy propionate, and and ethyl 3-ethoxypropionate), 2-alkoxypropionate alkyl esters such as methyl 2-alkoxypropionate, ethyl 2-alkoxypropionate, propyl 2-alkoxypropionate (for example, methyl 2-methoxypropionate, ethyl 2-methoxypropionate, propyl 2-methoxypropionate, methyl 2-ethoxypropionate, and ethyl 2-ethoxypropionate), methyl 2-alkoxy-2-methylpropionate such as methyl 2-methoxy-2-methylpropionate, ethyl 2-alkoxy-2-methylpropionate such as ethyl 2-ethoxy-2-methylpropionate, methyl pyruvate, ethyl pyruvate, propyl pyruvate, methyl acetoacetate, ethyl acetoacetate, methyl 2-oxobutanoate, and ethyl 2-oxobutanoate.

Examples of the ether solvent include diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate.

Examples of the ketone solvent include methyl ethyl ketone, cyclohexanone, cyclopentanone, 2-heptanone, 3-heptanone, and N-methyl-2-pyrrolidone (NMP).

Examples of the hydrocarbon solvent include limonene.

Examples of the aromatic hydrocarbon solvent include toluene, xylene, and anisole.

Examples of the sulfoxide solvent include dimethyl sulfoxide.

The solvent for component (B) is preferably y-butyrolactone, cyclopentanone, ethyl lactate, and 3-methoxy-N,N-dimethylpropanamide.

In the insulating membrane forming material in the present disclosure, from the viewpoint of reducing toxicity such as reproductive toxicity, a content of NMP may be 1 mass % or less with respect to a total amount of the insulating membrane forming material, and may be 3 mass % or less with respect to a total amount of the (A) polyimide precursor.

In the insulating membrane forming material in the present disclosure, a content of component (B) is preferably from 1 part by mass to 10,000 parts by mass, more preferably from 50 parts by mass to 10,000 parts by mass, with respect to 100 mass parts of the (A) polyimide precursor.

The (B) component preferably contains at least one of a solvent (1) which is at least one selected from the group consisting of compounds represented by Formulae (3) to (6), or a solvent (2) which is at least one selected from the group consisting of an ester solvent, an ether solvent, a ketone solvent, a hydrocarbon solvent, an aromatic hydrocarbon solvent, and a sulfoxide solvent.

A content of the solvent (1) may be from 5% by mass to 100% by mass, or from 5% by mass to 50% by mass, with respect to a total of the solvents (1) and (2).

A content of the solvent (1) may be from 10 parts by mass to 1000 parts by mass, from 10 parts by mass to 100 parts by mass, or from 10 parts by mass to 50 parts by mass, with respect to 100 parts by mass of the (A) polyimide precursor.

### ((C) Oxime-Based Photopolymerization Initiator)

The insulating membrane forming material in the present disclosure contains a (C) oxime-based photopolymerization initiator. This provides excellent exposure sensitivity and suppresses a generation of voids during joining. The (C) oxime-based photopolymerization initiator may be used singly or in combination of two or more kinds thereof.

From the viewpoint of providing excellent exposure sensitivity and suppressing a generation of voids during joining, it is preferable that the (C) oxime-based photopolymerization initiator contains a compound represented by the following Formula (I).

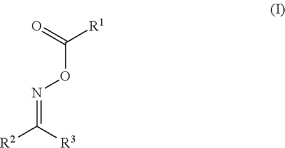

In Formula (I), R¹ represents an alkyl group, an alkoxy group, a phenyl group, or a phenoxy group, R² represents an alkyl group, and R³ represents a carbonyl group or a monovalent organic group linked by a single bond.

In Formula (I), R¹ is preferably an alkyl group, an alkoxy group, or a phenyl group, and more preferably an alkoxy group from the viewpoint of excellent resolution and pattern profile. On the other hand, from the viewpoint of increasing exposure sensitivity, R¹ is more preferably an alkyl group or a phenyl group.

From the viewpoint of excellent resolution and pattern profile while maintaining high exposure sensitivity, it is preferable to use a compound A in which R¹ in Formula (I) represents an alkoxy group in combination with a compound B in which R¹ in Formula (I) represents an alkyl group or a phenyl group.

A mixing ratio of the compound A to the compound B (compound A: compound B) is preferably from 1:1 to 1:0.01, more preferably from 1:0.5 to 1:0.01, and even more preferably from 1:0.2 to 1:0.01, based on mass.

A number of carbon atoms in the alkoxy group represented by R¹ is preferably from 1 to 10, more preferably from 1 to 5, and even more preferably from 1 to 3. The alkoxy group represented by R¹ may be linear, branched, or cyclic, and is preferably linear.

The number of carbon atoms in the alkyl group represented by R¹ is preferably 1 to 10, more preferably 1 to 5, and even more preferably 1 to 3. The alkyl group represented by R¹ may be linear, branched, or cyclic, and is preferably linear.

The alkyl group, alkoxy group, phenyl group and phenoxy group represented by R¹ may be substituted or unsubstituted, and is preferably unsubstituted.

In Formula (I), R² is preferably an alkyl group, more preferably an alkyl group having 1 to 10 carbon atoms, and even more preferably an alkyl group having 1 to 6 carbon atoms. The alkyl group represented by R² may be linear, branched, or cyclic, and is preferably linear.

In Formula (I), R³ represents a carbonyl group or a monovalent organic group linked by a single bond. The monovalent organic group may be a phenyl group which may have a substituent. Examples of the substituent on the phenyl group include a phenoxy group, a phenylthio group, a phenyl group, an amino group and an alkyl group, and these groups may further have a substituent. The substituents on the phenyl group may be bonded to each other to form a ring. Examples of the ring formed include a carbazole ring. The ring formed may further have a substituent. Examples of the substituent on the ring formed include an alkyl group, a phenyl group and an acyl group, and these groups may further have a substituent.

Specific examples of the (C) oxime-based photopolymerization initiator include 1-phenyl-1,2-butanedione-2-(O-methoxycarbonyl) oxime, 1-phenyl-1,2-propanedione-2-(O-methoxycarbonyl) oxime, 1-phenyl-1,2-propanedione-2-(O-ethoxycarbonyl) oxime, 1-phenyl-1,2-propanedione-2-(O-benzoyl) oxime, 1,3-diphenylpropanetrione-2-(O-ethoxycarbonyl) oxime,) oxime, 1-phenyl-3-ethoxypropanetrione-2-(O-benzoyl) oxime, 1-[4-(phenylthio)phenyl]octane-1,2-dione=2-(O-benzoyloxime), O-acetyl-1-[6-(2-methylbenzoyl)-9-ethyl-9H-carbazol-3-yl]ethanone oxime, and 1-[4-(4-hydroxyethyloxy-phenylthio)phenyl]-1,2-propanedione-2-(O-acetyloxime).

The insulating membrane forming material in the present disclosure may contain other photopolymerization initiators in addition to the (C) oxime-based photopolymerization initiator. Examples of the other photopolymerization initiators include acetophenone derivatives such as acetophenone, 2,2-diethoxyacetophenone, 3′-methylacetophenone, 2,2-dimethoxy-2-phenylacetophenone, 2-hydroxy-2-methylpropiophenone, 4′-(methylthio)-a-morpholino-a-methylpropiophenone, and 1-hydroxycyclohexylphenyl ketone; thioxanthone derivatives such as thioxanthone, 2-methylthioxanthone, 2-isopropylthioxanthone, 2-chlorothioxanthone, and diethylthioxanthone; benzil derivatives such as benzil, benzil dimethyl ketal, and benzyl-β-methoxyethyl acetal; benzoin derivatives such as benzoin, benzoin methyl ether, benzoin ethyl ether, benzoin phenyl ether, methyl benzoin, ethyl benzoin, and propyl benzoin; N-aryl glycines such as N-phenyl glycine; peroxides such as benzoyl perchloride; aromatic biimidazoles such as 2-(o-chlorophenyl)-4,5-diphenylimidazole dimer, 2-(o-fluorophenyl)-4,5-diphenylimidazole dimer, and 2-(o-or p-methoxyphenyl)-4,5-diphenylimidazole dimer; acylphosphine oxide derivatives such as 2,4,6-trimethylbenzoyl-diphenylphosphine oxide and bis(2,4,6-trimethylbenzoyl)phenylphosphine oxide, Irgacure OXE03 (manufactured by BASF), and Irgacure OXE04 (manufactured by BASF). The other photopolymerization initiators may be used singly or in combination of two or more kinds thereof.

A content of the (C) oxime-based photopolymerization initiator with respect to a total amount of photopolymerization initiators is preferably 60% by mass or more, more preferably 80% by mass or more, even more preferably 90% by mass or more, and particularly preferably 95% by mass or more.

A total amount of the photopolymerization initiator is preferably from 0.1 parts by mass to 20 parts by mass, more preferably from 1 part by mass to 20 parts by mass, and even more preferably from 5 parts by mass to 20 parts by mass, with respect to 100 parts by mass of the (A) polyimide precursor.

The insulating membrane forming material in the present disclosure contains the (A) polyimide precursor, the (B) solvent, and the (C) oxime-based photopolymerization initiator, and may contain a (D) sensitizer, a (E) polymerizable monomer, a (F) thermal polymerization initiator, a (G) polymerization inhibitor, an antioxidant, a coupling agent, a surfactant, a leveling agent, a rust inhibitor, a nitrogen-containing compound or the like as necessary, and may contain other components and unavoidable impurities within a range that does not impair the effects of the present disclosure. The insulating membrane forming material in the present disclosure preferably further contains the (D) component and the (E) component.

Hereinafter, the (D) sensitizer will also be referred to as the (D) component, the (E) polymerizable monomer as the (E) component, the (F) thermal polymerization initiator as the (F) component, and the (G) polymerization inhibitor as the (G) component.

The insulating membrane forming material in the present disclosure may, for example, contain 80% by mass or more, 90% by mass or more, 95% by mass or more, 98% by mass or more, or 100% by mass of

(A) polyimide precursor through (C) component,
(A) polyimide precursor through (D) component,
(A) polyimide precursor through (E) component,
(A) polyimide precursor through (F) component,
(A) polyimide precursor through (G) component, or
(A) polyimide precursor through (G) component and at least one selected from the group consisting of an antioxidant, a coupling agent, a surfactant, a leveling agent, a rust inhibitor, and a nitrogen-containing compound.

Preferred embodiments of each component are described below.

### ((D) Sensitizer)

The insulating membrane forming material in the present disclosure preferably contains a (D) sensitizer. Examples of the (D) sensitizer include benzophenone derivatives such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 4-chlorobenzophenone, 4,4′-dimethoxybenzophenone, 4,4′-diaminobenzophenone, 4,4′-bis(diethylamino)benzophenone, o-benzoylmethylbenzoate, 4-benzoyl-4′-methyldiphenyl ketone, dibenzyl ketone, fluorenone. The (D) sensitizer may be used singly or in combination of two or more kinds thereof.

In a case in which the insulating membrane forming material in the present disclosure contains the (D) sensitizer, a content of the (D) sensitizer is not particularly limited, and is preferably from 0.01 parts by mass to 3 parts by mass, and more preferably from 0.1 parts by mass to 1 part by mass, with respect to 100 parts by mass of the (A) polyimide precursor.

### ((E) Polymerizable Monomer)

The insulating membrane forming material in the present disclosure preferably contains a (E) polymerizable monomer. The (E) component preferably has at least one group containing a polymerizable unsaturated double bond, and more preferably has at least one (meth)acrylic group from the viewpoint of favorable polymerization by using in combination with a photopolymerization initiator. From the viewpoint of improving crosslink density and improving exposure sensitivity, it is preferable that the (E) component has 2 to 6 groups containing a polymerizable unsaturated double bond, and more preferably has 2 to 4 groups.

The polymerizable monomer may be used singly or in combination of two or more kinds thereof.

The polymerizable monomer having a (meth)acrylic group are not particularly limited, and examples thereof include diethylene glycol diacrylate, triethylene glycol diacrylate, tetraethylene glycol diacrylate, diethylene glycol dimethacrylate, triethylene glycol dimethacrylate, tetraethylene glycol dimethacrylate, 1,4-butanediol diacrylate, 1,6-hexanediol diacrylate, 1,4-butanediol dimethacrylate, 1,6-hexanediol dimethacrylate, trimethylolpropane diacrylate, trimethylolpropane triacrylate, trimethylolpropane dimethacrylate, trimethylolpropane trimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, ethoxylated pentaerythritol tetraacrylate, ethoxylated isocyanuric acid triacrylate, ethoxylated isocyanuric acid trimethacrylate, acryloyloxyethyl isocyanurate, methacryloyloxyethyl isocyanurate, tricyclodecane dimethanol diacrylate, 2-hydroxyethyl (meth)acrylate, 1,3-bis((meth)acryloyloxy)-2-hydroxypropane, ethylene oxide (EO) modified bisphenol A diacrylate, and ethylene oxide (EO) modified bisphenol A dimethacrylate.

The other polymerizable monomers other than those having a (meth)acrylic group are not particularly limited, and examples thereof include styrene, divinylbenzene, 4-vinyltoluene, 4-vinylpyridine, N-vinylpyrrolidone, methylene bisacrylamide, N,N-dimethylacrylamide, and N-methylolacrylamide.

The (E) component is not limited to a compound having a group containing a polymerizable unsaturated double bond, and may be a compound having a polymerizable group other than an unsaturated double bond group (for example, an oxirane ring).

In a case in which the insulating membrane forming material in the present disclosure contains the (E) component, a content of the (E) component is not particularly limited, and is preferably from 1 part by mass to 100 parts by mass, more preferably from 1 part by mass to 75 parts by mass, and even more preferably from 1 part by mass to 50 parts by mass, with respect to 100 parts by mass of the (A) polyimide precursor.

### ((F) Thermal Polymerization Initiator)

The insulating membrane forming material in the present disclosure may contain a (F) thermal polymerization initiator from the viewpoint of improving physical properties of the cured product thereof.

Specific examples of the (F) component include ketone peroxides such as methyl ethyl ketone peroxide, peroxyketals such as 1,1-di(t-hexylperoxy)-3,3,5-trimethylcyclohexane, 1,1-di(t-hexylperoxy) cyclohexane and 1,1-di(t-butylperoxy) cyclohexane, hydroperoxides such as 1,1,3,3-tetramethylbutyl hydroperoxide, cumene hydroperoxide, p-menthane hydroperoxide and diisopropylbenzene hydroperoxide, dialkyl peroxides such as dicumyl peroxide and di-t-butyl peroxide, diacyl peroxides such as dilauroyl peroxides and dibenzoyl peroxide, peroxydicarbonates such as di(4-t-butylcyclohexyl) peroxydicarbonate and di(2-ethylhexyl) peroxydicarbonate, peroxyesters such as t-butylperoxy-2-ethylhexanoate, t-hexylperoxyisopropyl monocarbonate, t-butylperoxybenzoate and 1,1,3,3-tetramethylbutylperoxy-2-ethylhexanoate, and bis(1-phenyl-1-methylethyl) peroxide. The thermal polymerization initiator may be used singly, or in combination of two or more kinds thereof.

In a case in which the insulating membrane forming material in the present disclosure contains the (F) component, a content of the (F) component may be from 0.1 parts by mass to 20 parts by mass, from 1 part by mass to 15 parts by mass, or from 1 part by mass to 10 parts by mass, with respect to 100 parts by mass of the polyimide precursor.

### ((G) Polymerization Inhibitor)

The insulating membrane forming material in the present disclosure may contain a (G) component in order to ensure excellent storage stability. Examples of the polymerization inhibitor include a radical polymerization inhibitor and a radical polymerization suppressor.

Specific examples of the (G) component include p-methoxyphenol, diphenyl-p-benzoquinone, benzoquinone, hydroquinone, pyrogallol, phenothiazine, resorcinol, ortho-dinitrobenzene, para-dinitrobenzene, meta-dinitrobenzene, phenanthraquinone, N-phenyl-2-naphthylamine, cupferron, 2,5-toluquinone, tannic acid, parabenzylaminophenol, nitrosamines, and a hindered phenol compound. The polymerization inhibitor may be used singly or in combination of two or more kinds thereof. Combining two or more kinds of polymerization inhibitors tends to make it easier to adjust the photosensitive characteristics due to differences in reactivity. The hindered phenol compound may have both a function of a polymerization inhibitor and a function of an antioxidant described below, or it may have only one of these functions.

The hindered phenol compound is not particularly limited, and examples thereof include 2,6-di-t-butyl-4-methylphenol, 2,5-di-t-butyl-hydroquinone, octadecyl-3-(3,5-di-t-butyl-4-hydroxyphenyl) propionate, isooctyl-3-(3,5-di-t-butyl-4-hydroxyphenyl) propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethylene glycol-bis [3-(3-t-butyl-5-methyl-4-hydroxyphenyl) propionate], 1,6-hexanediol-bis [3-(3,5-di-t-butyl-4-hydroxyphenyl) propionate], 2,2-thio-diethylenebis [3-(3,5-di-t-butyl-4-hydroxyphenyl) propionate], N,N′-hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaerythrityl tetrakis [3-(3,5-di-t-butyl-4-hydroxyphenyl) propionate], tris-(3,5-di-t-butyl-4-hydroxybenzyl)-isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris [4-(1-ethylpropyl)-3-hydroxy-2,6-dimethylbenzyl]-1,3,5-triazine-2,4,6-(1H,3H,5H)-trione, 1,3,5-tris [4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-dimethylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione, 1,3,5-tris(4-t-butyl-5-ethyl-3-hydroxy-2-methylbenzyl)-1,3,5-triazine-2,4,6-(1H,3H,5H)-trione, N,N′-hexane-1,6-diylbis [3-(3,5-di-tert-butyl-4-hydroxyphenyl) propionamide], and 1,4,4-trimethyl-2,3-diazabicyclo [3.2.2]nona-2-ene-2,3-dioxide.

In a case in which the insulating membrane forming material in the present disclosure contains the (G) component, a content of the (G) component is preferably from 0.01 parts by mass to 30 parts by mass, more preferably from 0.01 parts by mass to 10 parts by mass, and even more preferably from 0.05 parts by mass to 5 parts by mass, with respect to 100 parts by mass of the (A) polyimide precursor, from the viewpoint of a storage stability of the insulating membrane forming material and a heat resistance of a resulting cured product.

### (Antioxidant)

The insulating membrane forming material in the present disclosure may contain an antioxidant from the viewpoint of suppressing a decrease in adhesion by capturing an oxygen radical and a peroxide radical generated during high-temperature storage, reflow treatment or the like. By containing an antioxidant in the insulating membrane forming material in the present disclosure, oxidation of an electrode during insulation reliability testing may be suppressed.

Specific examples of the antioxidant include the compounds exemplified above as the hindered phenol compound, N,N′-bis [2-[2-(3,5-di-tert-butyl-4-hydroxyphenyl)ethylcarbonyloxy]ethyl]oxamide, N,N′-bis-3-(3,5-di-tert-butyl-4′-hydroxyphenyl) propionylhexamethylenediamine, 1,3,5-tris(3-hydroxy-4-tert-butyl-2,6-dimethylbenzyl)-1,3,5-triazine-2,4,6 (1H,3H,5H)-trione, and 1,3,5-tris(4-t-butyl-3-hydroxy-2,6-dimethylbenzyl) isocyanuric acid.

The antioxidants may be used singly or in combination of two or more kinds thereof.

In a case in which the insulating membrane forming material in the present disclosure contains the antioxidant, a content of the antioxidant is preferably from 0.1 parts by mass to 20 parts by mass, more preferably from 0.1 parts by mass to 10 parts by mass, and even more preferably from 0.1 parts by mass to 5 parts by mass, with respect to 100 parts by mass of the (A) polyimide precursor.

### (Coupling Agent)

The insulating membrane forming material in the present disclosure may contain a coupling agent. In the heat treatment, the coupling agent reacts with the (A) polyimide precursor to crosslink, or the coupling agent itself polymerizes. This tends to further improve an adhesion between an obtained cured product and a substrate.

Specific examples of the coupling agent are not particularly limited. Examples of the coupling agent include a silane coupling agent such as 3-aminopropyltrimethoxysilane, N-(2-aminoethyl)-3-aminopropylmethyldimethoxysilane, 3-glycidoxypropylmethyldimethoxysilane, 3-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl) succinimide, N-[3-(triethoxysilyl) propyl]phthalamic acid, benzophenone-3,3′-bis(N-[3-triethoxysilyl]propylamido)-4,4′-dicarboxylic acid, benzene-1,4-bis(N-[3-triethoxysilyl]propylamido)-2,5-dicarboxylic acid, 3-(triethoxysilyl) propyl succinic anhydride, N-phenylaminopropyltrimethoxysilane, N,N′-bis(2-hydroxyethyl)-3-aminopropyltriethoxysilane, and 3-ureidopropyltriethoxysilane; and aluminum-based adhesion assistant such as aluminum tris(ethylacetoacetate), aluminum tris(acetylacetonate), and ethylacetoacetate aluminum diisopropylate.

The coupling agent may be used singly or in combination of two or more kinds thereof.

In a case in which the insulating membrane forming material in the present disclosure contains the coupling agent, a content of the coupling agent is preferably from 0.1 parts by mass to 20 parts by mass, more preferably from 0.3 parts by mass to 10 parts by mass, and even more preferably from 1 part by mass to 10 parts by mass, with respect to 100 parts by mass of the (A) polyimide precursor.

### (Surfactant and Leveling Agent)

The insulating membrane forming material in the present disclosure may contain at least one of a surfactant or a leveling agent. By including at least one of a surfactant or a leveling agent in the insulating membrane forming material, it is possible to improve a coatability (for example, suppression of striations (unevenness in film thickness)), an adhesion, a compatibility of compounds in the insulating membrane forming material or the like.

Examples of the surfactant or the leveling agent include polyoxyethylene uraryl ether, polyoxyethylene stearyl ether, polyoxyethylene oleyl ether, and polyoxyethylene octylphenol ether.

The surfactant and the leveling agent may be used singly or in combination of two or more kinds thereof.

In a case in which the insulating membrane forming material in the present disclosure includes at least one of a surfactant or a leveling agent, a total content of the surfactant and the leveling agent is preferably from 0.01 parts by mass to 10 parts by mass, more preferably from 0.05 parts by mass to 5 parts by mass, and even more preferably from 0.05 parts by mass to 3 parts by mass, with respect to 100 parts by mass of (A) polyimide precursor.

### (Rust Inhibitor)

The insulating membrane forming material in the present disclosure may include a rust inhibitor from the viewpoint of suppressing corrosion of a metal such as copper and copper alloys, and from the viewpoint of suppressing discoloration of the metal. Examples of the rust inhibitor include an azole compound and a purine derivative.

Specific examples of the azole compound include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(a,a-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole, and 1-methyl-1H-tetrazole.

Specific examples of the purine derivative include purine, adenine, guanine, hypoxanthine, xanthine, theobromine, caffeine, uric acid, isoguanine, 2,6-diaminopurine, 9-methyladenine, 2-hydroxyadenine, 2-methyladenine, 1-methyladenine, N-methyladenine, N,N-dimethyladenine, 2-fluoroadenine, 9-(2-hydroxyethyl) adenine, guanine oxime, N-(2-hydroxyethyl) adenine, 8-aminoadenine, 6-amino-8-phenyl-9H-purine, 1-ethyladenine, 6-ethylaminopurine, 1-benzyladenine, N-methylguanine, 7-(2-hydroxyethyl) guanine, N-(3-chlorophenyl) guanine, N-(3-ethylphenyl) guanine, 2-azaadenine, 5-azaadenine, 8-azaadenine, 8-azaguanine, 8-azapurine, 8-azaxanthine, 8-azahypoxanthine, and derivatives thereof.

The rust inhibitor may be used singly or in combination of two or more kinds thereof.

In a case in which the insulating membrane forming material in the present disclosure contains the rust inhibitor, a content of the rust inhibitor is preferably from 0.01 parts by mass to 10 parts by mass, more preferably from 0.1 parts by mass to 5 parts by mass, and even more preferably from 0.5 parts by mass to 3 parts by mass, with respect to 100 parts by mass of the (A) polyimide precursor. In particular, in a case in which the insulating membrane forming material in the present disclosure is applied to a surface of copper or a copper alloy, discoloration of the surface of copper or copper alloy is suppressed by a content of the rust inhibitor being 0.1 parts by mass or more.

The insulating membrane forming material in the present disclosure may contain a nitrogen-containing compound from the viewpoint of accelerating an imidization reaction of the component (A) to obtain a cured product with high reliability.

Specific examples of the nitrogen-containing compound include 2-(methylphenylamino) ethanol, 2-(ethylanilino) ethanol, N-phenyldiethanolamine, N-methylaniline, N-ethylaniline, N,N′-dimethylaniline, N-phenylethanolamine, 4-phenylmorpholine, 2,2′-(4-methylphenylimino) diethanol, 4-aminobenzamide, 2-aminobenzamide, nicotinamide, 4-amino-N-methylbenzamide, 4-aminoacetanilide, and 4-aminoacetophenone. Among these, N-phenyldiethanolamine, N-methylaniline, N-ethylaniline, N,N′-dimethylaniline, N-phenylethanolamine, 4-phenylmorpholine, 2,2′-(4-methylphenylimino) diethanol and the like are preferred. The nitrogen-containing compound may be used singly or in combination of two or more kinds thereof.

The nitrogen-containing compound preferably includes a compound represented by the following Formula (17).

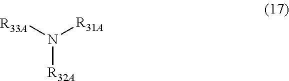

In Formula (17), each of R_{31A} to R_{33A} is independently a hydrogen atom, a monovalent aliphatic hydrocarbon group, a monovalent aliphatic hydrocarbon group having a hydroxyl group, or a monovalent aromatic group, and at least one (preferably one) of R_{31A} to R_{33A} is a monovalent aromatic group. Adjacent groups of R_{31A} to R_{33A} may be linked to each other to form a ring structure. Examples of the ring structure formed include a 5-membered ring or a 6-membered ring that may have a substituent such as a methyl group or a phenyl group. A hydrogen atom of the monovalent aliphatic hydrocarbon group may be substituted with a functional group other than a hydroxyl group.

In Formula (17), it is preferable that at least one (preferably one) of R_{31A} to R_{33A} is a monovalent aliphatic hydrocarbon group, a monovalent aliphatic hydrocarbon group having a hydroxyl group, or a monovalent aromatic group.

In Formula (17), the monovalent aliphatic hydrocarbon group represented by R³¹A to R_{33A} preferably have from 1 to 10 carbon atoms, and more preferably from 1 to 6 carbon atoms. The monovalent aliphatic hydrocarbon group is preferably a methyl group, an ethyl group or the like.

In Formula (17), the monovalent aliphatic hydrocarbon group having a hydroxyl group represented by R_{31A} to R_{33A} is preferably a group in which one or more hydroxyl groups are bonded to the monovalent aliphatic hydrocarbon group represented by R_{31A} to R_{33A}, more preferably a group in which one to three hydroxyl groups are bonded. Specific examples of the monovalent aliphatic hydrocarbon group having a hydroxyl group include a methylol group and a hydroxyethyl group, and among these, a hydroxyethyl group is preferred.

Examples of the monovalent aromatic group represented by R_{31A} to R_{33A} in Formula (17) include a monovalent aromatic hydrocarbon group and a monovalent aromatic heterocyclic group, and the monovalent aromatic hydrocarbon group is preferred. The monovalent aromatic hydrocarbon group preferably has from 6 to 12 carbon atoms, and more preferably has 6 to 10 carbon atoms.

Example of the monovalent aromatic hydrocarbon group include a phenyl group and a naphthyl group.

The monovalent aromatic group represented by R_{31A} to R_{33A} in Formula (17) may have a substituent. Examples of the substituent include a same group as the monovalent aliphatic hydrocarbon group represented by R_{31A} to R_{33A} in Formula (17) and the monovalent aliphatic hydrocarbon groups having a hydroxyl group represented by R_{31A} to R_{33A} in Formula (17).

In a case in which the resin composition in the present disclosure contains a nitrogen-containing compound, a content of the nitrogen-containing compound is preferably from 0.1 parts by mass to 20 parts by mass with respect to 100 parts by mass of component (A), and from the viewpoint of storage stability, more preferably from 0.3 parts by mass to 15 parts by mass, and even more preferably from 0.5 parts by mass to 10 parts by mass.

### (Characteristics of Insulating Membrane Forming Material)

From the viewpoint of low-temperature joint, the insulating membrane forming material in the present disclosure preferably has a glass transition temperature of from 50° C. to 300° C., and more preferably 50° C. to 250° C. in a state of a cured product. The glass transition temperature of the cured product may be 200° C. or lower.

The glass transition temperature of the cured product is measured as follows. First, an insulating membrane forming material is heated for 2 hours in a nitrogen atmosphere at a predetermined curing temperature (for example, from 150° C. to 375° C.) at which a curing reaction can occur, to obtain a cured product. The obtained cured product is cut into a rectangular parallelepiped of 5 mm×50 mm×3 mm, and the dynamic viscoelasticity is measured in a dynamic viscoelasticity measuring device (for example, RSA-G2, manufactured by TA Instruments) using a tensile tool at a frequency of 1 Hz and a heating rate of 5° C./min in a temperature range of from 50° C. to 350° C. The glass transition temperature (Tg) is a temperature at a peak top of tan 8 calculated from a ratio of a storage modulus and a loss modulus obtained by the above method.

The insulating membrane forming material in the present disclosure may be a negative photosensitive insulating membrane forming material or a positive photosensitive insulating membrane forming material. In addition, the negative photosensitive insulating membrane forming material or the positive photosensitive insulating membrane forming material may be used for at least one of providing plural through holes for arranging plural terminal electrodes in a first organic insulating membrane provided on one surface of a first substrate body described below, or providing plural through holes for arranging plural terminal electrodes in a second organic insulating membrane provided on one surface of a second substrate body.

The insulating membrane forming material in the present disclosure has a thermal expansion coefficient of preferably 150 ppm/K or less in a state of a cured product, more preferably 100 ppm/K or less, and even more preferably 70 ppm/K or less. As a result, the thermal expansion coefficient of the insulating membrane, which is the cured product, is equal to or close to the thermal expansion coefficient of the electrodes, so that even if heat is generated during use of the semiconductor device, damage to the semiconductor device due to the difference in the thermal expansion coefficient between the insulating layer and the electrodes may be suppressed. The thermal expansion coefficient is a rate at which the length of the cured product expands due to an increase in temperature, expressed per temperature. The thermal expansion coefficient may be calculated by measuring a change in length of the cured product at from 100° C. to 150° C. using a thermomechanical analyzer or the like.

From the viewpoint of suppressing a occurrence of voids in joining or the like, the insulating membrane forming material in the present disclosure preferably has a 5% thermal weight loss temperature of 200° C. or higher, and more preferably 250° C. or higher, in a state of a cured product.

The 5% thermal weight loss temperature is calculated by using 10 mg of polyimide resin membrane as a measurement sample and measuring a temperature at which a weight of the measurement sample decreases by 5% when the temperature is increased from 25° C. to 800° C. at 10° C. per minute using a differential thermal and thermogravimetric simultaneous measurement device.

### <Semiconductor Device>

A semiconductor device in the present disclosure includes a first semiconductor substrate having a first substrate body, and a first organic insulating membrane and a first electrode provided on one surface of the first substrate body; and a semiconductor chip having a semiconductor chip substrate body, and a second organic insulating membrane and a second electrode provided on one surface of the semiconductor chip substrate body, in which the first organic insulating membrane and the second organic insulating membrane are joined to each other, and the first electrode and the second electrode are joined to each other, and at least one of the first organic insulating membrane or the second organic insulating membrane is a cured product of the hybrid bonding insulating membrane forming material in the present disclosure.

The semiconductor device in the present disclosure has fewer voids at the joint interface of the insulating membrane, since at least one of the first organic insulating membrane or the organic insulating membrane portion is a cured product of the insulating membrane forming material in the present disclosure.

### <Method of Producing Semiconductor Device>

In a method of producing a semiconductor device in the present disclosure, a semiconductor device is produced using the insulating membrane forming material in the present disclosure. Specifically, the method of producing a semiconductor device in the present disclosure includes: preparing a first semiconductor substrate having a first substrate body, and a first electrode and a first organic insulating membrane provided on one surface of the first substrate body; preparing a semiconductor chip having a semiconductor chip substrate body, and a second organic insulating membrane and a second electrode provided on one surface of the semiconductor chip substrate body; and joining the first electrode to the second electrode, and bonding the first organic insulating membrane to the second organic insulating membrane, in which the hybrid bonding insulating membrane forming material according to any one of claims 1 to 12 is used in production of at least one of the first organic insulating membrane or the second organic insulating membrane.

Hereinafter, an embodiment of a semiconductor device in the present disclosure and an embodiment of a method of producing a semiconductor device in the present disclosure will be described in detail with reference to the figures. In the following description, the same or equivalent parts are denoted by the same reference numerals, and duplicated descriptions will be omitted. Furthermore, unless otherwise specified, the positional relationships, such as up, down, left, right or the like are based on the positional relationships shown in the figures. Furthermore, the dimensional ratios of the figures are not limited to the ratios shown in the drawings.

### (One Example of Semiconductor Device)

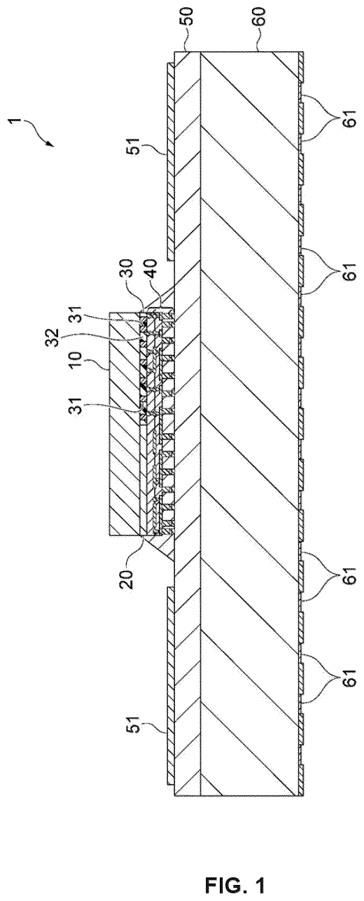

FIG. 1 is a cross-sectional view showing an example of a semiconductor device in the present disclosure. As shown in FIG. 1, the semiconductor device 1 is, for example, an example of a semiconductor package, and includes a first semiconductor chip 10 (first semiconductor substrate), a second semiconductor chip 20 (semiconductor chip), a pillar portion 30, a rewiring layer 40, a substrate 50, and a circuit board 60.

The first semiconductor chip 10 is a semiconductor chip such as an LSI (large-scale integrated circuit) chip or a CMOS (Complementary Metal Oxide Semiconductor) sensor, in which the second semiconductor chip 20 is mounted downward in a three-dimensional mounting structure. The second semiconductor chip 20 is a semiconductor chip such as an LSI or memory or the like, and is a chip component having a smaller area in a planar view than the first semiconductor chip 10. The second semiconductor chip 20 is bonded to a back surface of the first semiconductor chip 10 by chip-to-chip (C2C) bonding. The first semiconductor chip 10 and the second semiconductor chip 20 have their respective terminal electrodes and the insulating membranes surrounding the periphery thereof, and are firmly and densely joined by hybrid bonding, the details of which will be described later.

The pillar portion 30 is a connection portion in which plural pillars 31 formed of a metal such as copper (Cu) are sealed with a resin 32. The plural pillars 31 are conductive members extending from an upper surface of the pillar portion 30 to a lower surface. The plural pillars 31 may have a cylindrical shape with a diameter of, for example, from 3 μm to 20 μm (5 μm in one example), and may be arranged so that a center-to-center distance between each pillar 31 is 15 μm or less. The plural pillars 31 flip-chip connect a lower terminal electrode of the first semiconductor chip 10 and a upper terminal electrode of the rewiring layer 40. By using the pillar portion 30, the semiconductor device 1 may form a connection electrode without using a technique called TMV (Through mold via), which is a technique of drilling holes in a mold and soldering the mold. The pillar portion 30 has, for example, a thickness similar to that of the second semiconductor chip 20, and is arranged on a side of the second semiconductor chip 20 in the horizontal direction. Note that, instead of the pillar portion 30, plural solder balls may be arranged, and the lower terminal electrode of the first semiconductor chip 10 and the upper terminal electrode of the rewiring layer 40 may be electrically connected by the solder balls.

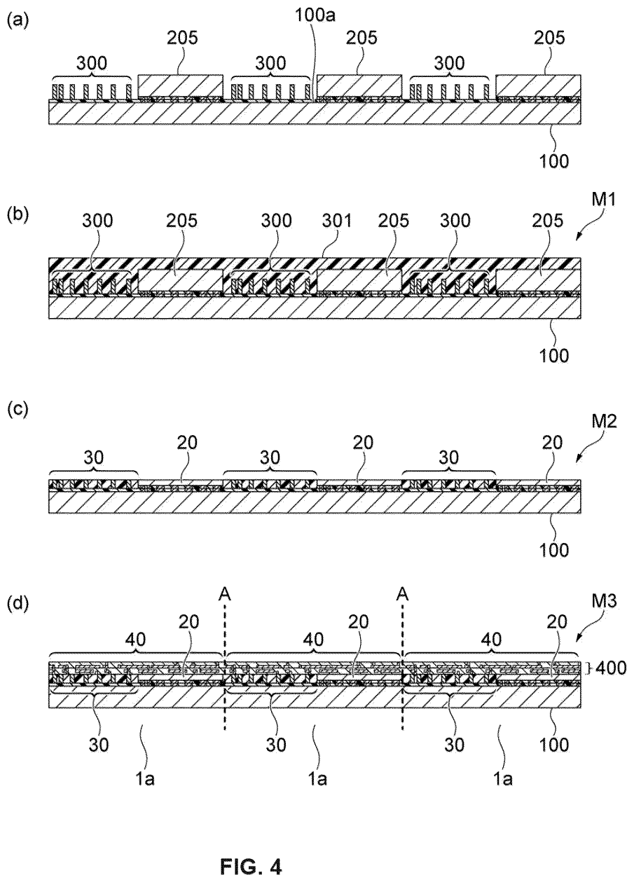

The rewiring layer 40 is a wiring layer having a terminal pitch conversion function, which is a function of the package substrate, and may be a layer in which a rewiring pattern is formed with polyimide, copper wiring or the like on the insulating membrane on a lower side of the second semiconductor chip 20 and on a lower surface of the pillar portion 30. The rewiring layer 40 is formed in a state in which the first semiconductor chip 10, the second semiconductor chip 20 or the like are turned upside down (see (d) of FIG. 4).

The rewiring layer 40 electrically connects a terminal electrode on a lower surface of the second semiconductor chip 20 and a terminal electrode of the first semiconductor chip 10 via the pillar portion 30 to a terminal electrode of the substrate 50. A terminal pitch of the substrate 50 is wider than a terminal pitch of the pillar 31 and a terminal pitch of the second semiconductor chip 20. Various electronic components 51 may be mounted on the substrate 50. In a case in which there is a large difference in the terminal pitch between the rewiring layer 40 and the substrate 50, an inorganic interposer or the like may be used between the rewiring layer 40 and the substrate 50 to establish electrical connection between the rewiring layer 40 and the substrate 50.

The circuit board 60 is a board on which the first semiconductor chip 10 and the second semiconductor chip 20 are mounted, and has plural through electrodes inside which are electrically connected to the board 50 connected to the first semiconductor chip 10, the second semiconductor chip 20 and the electronic components 51. In the circuit board 60, each terminal electrodes of the first semiconductor chip 10 and the second semiconductor chip 20 are electrically connected to a terminal electrodes 61 provided on a back surface of the circuit board 60 by plural through electrodes.

### (One Example of Method of Producing Semiconductor Device)

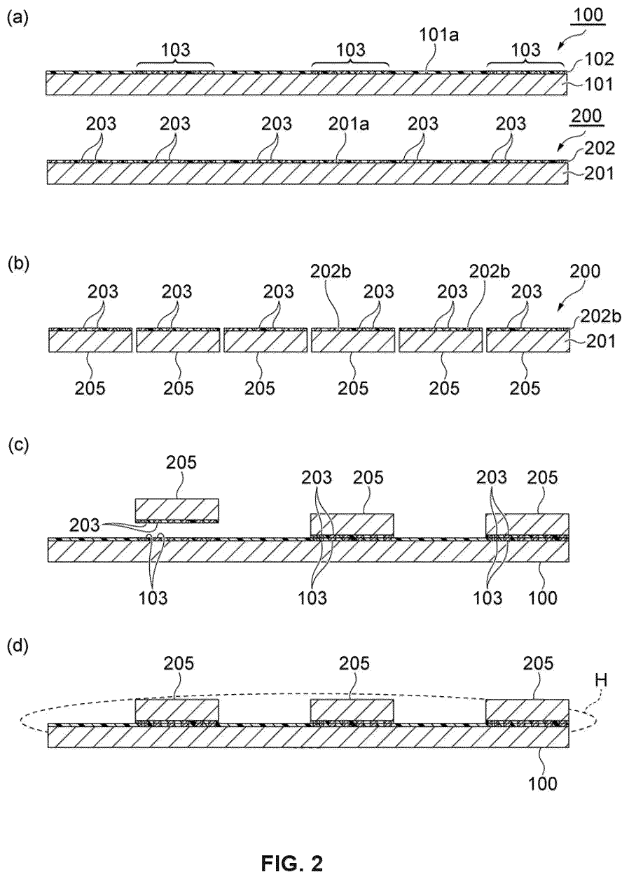

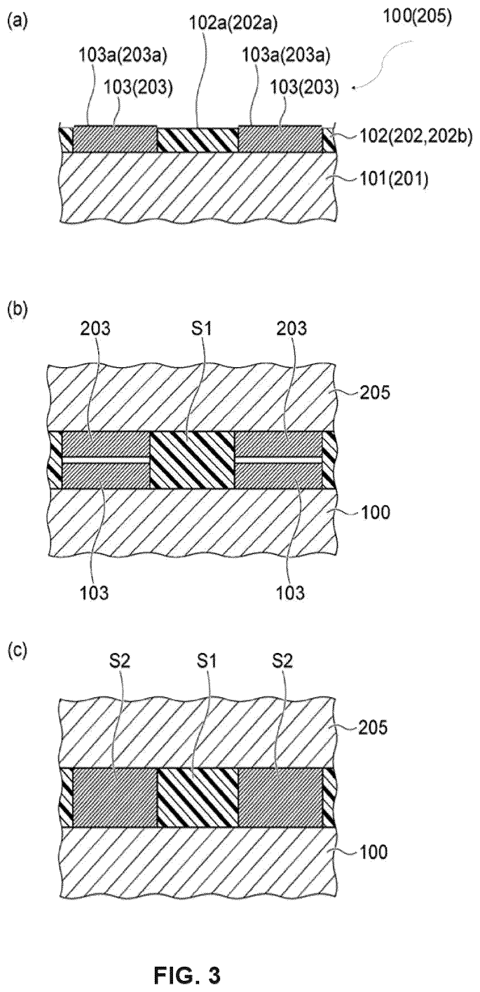

Next, an example of a method of producing a semiconductor device 1 will be described with reference to FIGS. 2 to 4. FIG. 2 is a diagram showing a method of producing the semiconductor device shown in FIG. 1 in sequence. FIG. 3 is a diagram showing in more detail a joining method (hybrid bonding) in a method of producing the semiconductor device shown in FIG. 2. FIG. 4 is a diagram showing a method of producing the semiconductor device shown in FIG. 1, and showing the processes following the process shown in FIG. 2 in sequence.

The semiconductor device 1 may be produced, for example, through the following processes (a) to (n).
(a) A process of preparing a first semiconductor substrate 100 corresponding to the first semiconductor chip 10.
(b) A process of preparing a second semiconductor substrate 200 corresponding to the second semiconductor chip 20.
(c) A process of polishing the first semiconductor substrate 100.
(d) A process of polishing the second semiconductor substrate 200.
(e) A process of singulating the second semiconductor substrate 200 to obtain plural semiconductor chips 205.
(f) A process of aligning terminal electrodes 203 of each of plural semiconductor chips 205 with terminal electrodes 103 of the first semiconductor substrate 100.
(g) A process of bonding an insulating membrane 102 of the first semiconductor substrate 100 and each insulating membrane portions 202b of the plural semiconductor chips 205 to each other (see FIG. 3(b)).
(h) A process of joining terminal electrodes 103 of the first semiconductor substrate 100 to terminal electrodes 203 of each of plural semiconductor chips 205 (see FIG. 3C).
(i) A process of forming plural pillars 300 (corresponding to pillars 31) between the plural semiconductor chips 205 on a connection surface of the first semiconductor substrate 100.
(j) A process of molding a resin 301 on the connection surface of the first semiconductor substrate 100 so as to cover the semiconductor chips 205 and the pillars 300 to obtain a semi-finished product M1.
(k) A process of grinding and thinning a resin 301 side of the semi-finished product M1 molded in process (j) to obtain a semi-finished product M2.
(l) A process of forming a wiring layer 400 corresponding to the rewiring layer 40 on the semi-finished product M2 thinned in process (k).
(m) A process of cutting a semi-finished product M3 on which the wiring layer 400 has been formed in process (1) along the cutting line A to obtain an individual semiconductor devices 1.
(n) A process of inverting a semiconductor device 1a individualized in process (m) and placing it on a substrate 50 and a circuit board 60 (see FIG. 1).

The insulating membrane forming material in the present disclosure may be an insulating membrane forming material for use in producing at least one insulating membrane of the first organic insulating membrane or the second organic insulating membrane in a method of producing a semiconductor device including at least one process corresponding to process (f) and processes (i) to (n).

[Processes (a) and (b)]

Process (a) is a process of preparing a first semiconductor substrate 100, which corresponds to plural first semiconductor chips 10 and is a silicon substrate on which an integrated circuit having semiconductor elements, wirings connecting them or the like is formed. In process (a), as shown in FIG. 2(a), plural terminal electrodes 103 (first electrodes) made of copper, aluminum or the like are provided at predetermined intervals on one surface 101a of a first substrate body 101 made of silicon or the like, and an insulating membrane 102 (first insulating membrane) which is a cured product of the insulating membrane forming material in the present disclosure is provided in a space between the electrodes. The plural terminal electrodes 103 may be provided after the insulating membrane 102 is provided on one surface 101a of the first substrate body 101, or the insulating membrane 102 may be provided after the terminal electrodes 103 are provided on the one surface 101a of the first substrate body 101. A predetermined interval is provided between the plural terminal electrodes 103 in order to form the pillars 300 in a process described later, and another terminal electrode (not shown) connected to the pillars 300 is formed between them.

Process (b) is a process of preparing a second semiconductor substrate 200, which corresponds to plural second semiconductor chips 20 and is a silicon substrate on which an integrated circuit having semiconductor elements, wirings connecting them or the like is formed. In process (b), as shown in FIG. 2(a), plural terminal electrodes 203 (plural second electrodes) made of copper, aluminum or the like are continuously provided on one surface 201a of a second substrate body 201 made of silicon or the like, and an insulating membrane 202 (second insulating membrane, organic insulating region) which is a cured product of the insulating membrane forming material in the present disclosure is provided. The plural terminal electrodes 203 may be provided after the insulating membrane 202 is provided on one surface 201a of the second substrate body 201, or the insulating membrane 202 may be provided after the terminal electrodes 203 are provided on the one surface 201a of the second substrate body 201.

The insulating membranes 102 and 202 used in processes (a) and (b) may both be cured products of the insulating membrane forming material in the present disclosure, or one of the insulating membranes 102 or 202 may be a cured product of the insulating membrane forming material in the present disclosure and the other may be another cured product. Examples of an insulating membrane forming material for forming the other cured product include those that do not contain the (A) polyimide precursor and contain other resins other than the (A) polyimide precursor, and those that do not contain the (C) oxime-based photopolymerization initiator. Examples of the other resins include insulating membrane forming materials that contain polyimide precursors without a polymerizable unsaturated bonding site, polyimides, polyamideimides, benzocyclobutene (BCB), polybenzoxazole (PBO), and PBO precursors. A tensile modulus of elasticity of the insulating membranes 102 and 202 at 25° C. is preferably each independently 7.0 GPa or less, more preferably 5.0 GPa or less, even more preferably 3.0 GPa or less, particularly preferably 2.0 GPa or less, and remarkably preferably 1.5 GPa or less.

Thermal expansion coefficients of the insulating membranes 102 and 202 are preferably 150 ppm/K or less, more preferably 100 ppm/K or less, and even more preferably 90 ppm/K or less, independently.

Thicknesses of the insulating membranes 102 and 202 are preferably from 0.1 μm to 50 μm, more preferably from 1 μm to 15 μm, independently. This ensures uniformity in the thickness of the insulating membrane while shortening a processing time in the subsequent polishing processes.

From the viewpoint of facilitating an operations in processes (c) and (d) and simplifying these processes, it is preferable that at least one of the following (and preferably both): a polishing rate of the insulating membrane 102 is from 0.1 times to 5 times a polishing rate of the terminal electrode 103, and a polishing rate of the insulating membrane 202 is from 0.1 times to 5 times a polishing rate of the terminal electrode 203. As an example, in a case in which the terminal electrode 103 or 203 is made of copper and a polishing rate of copper is 50 nm/min, the polishing rate of the insulating membrane 102 or 202 is preferably 200 nm/min or less (i.e., four times the polishing rate of copper or less), more preferably 100 nm/min or less (i.e., twice the polishing rate of copper or less), and even more preferably 50 nm/min or less (i.e., equal to or less than the polishing rate of copper).

Next, a method of producing an insulating membrane will be described. An insulating membrane is obtained by curing an insulating membrane forming material. Examples of the method of producing an insulating membrane include (a) a method including a process of applying an insulating membrane forming material onto a substrate and drying it to form a resin membrane, and a process of heat-treating the resin membrane, and (B) a method including a process of forming a resin membrane of a certain thickness using an insulating membrane forming material on a film that has been subjected to a release treatment, and then transferring the resin membrane to a substrate by a lamination method, and a process of heat-treating the resin membrane formed on the substrate after transfer. From the viewpoint of flatness, the above-mentioned method (a) is preferred.

Examples of methods for applying the insulating membrane forming material include spin coating, inkjet, and slit coating.

In the spin coating method, the insulating membrane forming material may be spin-coated under conditions such as a rotation speed from 300 rpm (revolutions per minute) to 3,500 rpm, and preferably from 500 rpm to 1,500 rpm, an acceleration from 500 rpm/sec to 15,000 rpm/sec, and a rotation time from 30 seconds to 300 seconds.

A drying process may be included after the insulating membrane forming material is applied to a support, film or the like. Drying may be performed using a hot plate, oven, or the like. A drying temperature is preferably from 75° C. to 130° C., and from the viewpoint of improving a flatness of the insulating membrane, more preferably from 90° C. to 120° C. A drying time is preferably from 30 seconds to 5 minutes.

Drying may be performed two or more times. This makes it possible to obtain a resin membrane in which the insulating membrane forming material described above is formed into a film shape.

In the slit coating method, the insulating membrane forming material may be slit coated under the following conditions: a material discharge speed from 10 μL/sec to 400 μL/sec, a material discharge part height from 0.1 μm to 1.0 μm, a stage speed (or material discharge part speed) from 1.0 mm/sec to 50.0 mm/sec, a stage acceleration from 10 mm/sec to 1000 mm/sec, a ultimate vacuum during reduced pressure drying from 10 Pa to 100 Pa, a drying time under reduced pressure from 30 seconds to 600 seconds, a drying temperature from 60° C. to 150° C., and a drying time 30 to 300 seconds.

The formed resin membrane may be heat treated. A heating temperature is preferably from 150° C. to 450° C., and more preferably from 150° C. to 350° C. By keeping the heating temperature within the above range, it is possible to suppress damage to the substrate, device or the like, and reduce the energy required for the process, while suitably producing the insulating membrane.

A heating time is preferably 5 hours or less, and more preferably from 30 minutes to 3 hours. By keeping the heating time within the above range, a crosslinking reaction or a ring-closing reaction by dehydration may proceed sufficiently.

A heating atmosphere may be air or an inert atmosphere such as nitrogen, and preferably a nitrogen atmosphere from the viewpoint of preventing oxidation of the resin membrane.

Equipment used for the heating treatment may include a quartz tube furnace, a hot plate, a rapid thermal annealer, a vertical diffusion furnace, an infrared curing furnace, an electron beam curing furnace, a microwave curing furnace, or the like.

In a case in which the insulating membrane forming material in the present disclosure, which is a negative-type photosensitive insulating membrane forming material or a positive-type photosensitive insulating membrane forming material, is used, when forming the insulating membrane 202 on one surface 201a of the second substrate body 201 and then providing the plural terminal electrodes 203, for example, a method including: a process of applying the insulating membrane forming material onto a substrate; a process of drying to form a resin membrane; a process of exposing the resin membrane to a pattern and developing it with a developer to obtain a patterned resin membrane; and a process of heat-treating the patterned resin membrane; may be used. This makes it possible to obtain a cured patterned insulating membrane.

Alternatively, when providing the insulating membrane 202 on one surface 201a of the second substrate body 201 and then providing the plural terminal electrodes 203, for example, a method including: a process of applying an insulating membrane forming material other than the insulating membrane forming material in the present disclosure onto a substrate; a process of drying to form a resin membrane; a process of applying an insulating membrane forming material in the present disclosure, which is a negative type photosensitive insulating membrane forming material or a positive type photosensitive insulating membrane forming material, onto the resin membrane, drying, and then performing pattern exposure and developing using a developer to obtain a patterned resin membrane; and a process of heat treating the patterned resin membrane; may be used. This allows a cured patterned insulating membrane to be obtained.

Examples of the pattern exposure include exposing through a photomask to a predetermined pattern. Examples of an active light to be irradiated include i-rays, broadband ultraviolet rays, visible light and radiation, and i-rays are preferable. Examples of an exposure device that may be used include a parallel exposure device, a projection exposure device, a stepper, and a scanner exposure device.

By developing after exposure, a patterned resin membrane, which is a resin membrane having a pattern formed therein, may be obtained. In a case in which the insulating membrane forming material in the present disclosure is a negative-type photosensitive insulating membrane forming material, an unexposed areas are removed with a developer.

As an organic solvent used as the negative developer, a good solvent for the photosensitive resin membrane may be used singly, or a suitable mixture of a good solvent and a poor solvent may be used.

Examples of the good solvent include N-methyl-2-pyrrolidone, N-acetyl-2-pyrrolidone, N,N-dimethylacetamide, N,N-dimethylformamide, dimethylsulfoxide, y-butyrolactone, a-acetyl-y-butyrolactone, 3-methoxy-N,N-dimethylpropanamide, cyclopentanone, cyclohexanone, and cycloheptanone.

Examples of the poor solvent include toluene, xylene, methanol, ethanol, isopropanol, propylene glycol monomethyl ether acetate, propylene glycol monomethyl ether, and water.

In a case in which the insulating membrane forming material in the present disclosure is a positive photosensitive insulating membrane forming material, the exposed portion is removed with a developer.

Examples of a solution used as the positive developer include tetramethylammonium hydroxide (TMAH) solution and sodium carbonate solution.

At least one of the negative developer or the positive developer may contain a surfactant. A content of the surfactant is preferably from 0.01 parts by mass to 10 parts by mass, and more preferably from 0.1 parts by mass to 5 parts by mass, with respect to 100 parts by mass of the developer.

A development time may be, for example, twice the time it takes for a photosensitive resin membrane to be immersed in the developer and for the resin membrane to be completely dissolved.

The development time may be adjusted according to the (A) polyimide precursor contained in the insulating membrane forming material in the present disclosure, and is, for example, preferably from 10 seconds to 15 minutes, more preferably from 10 seconds to 5 minutes, and even more preferably from 20 seconds to 5 minutes from the viewpoint of productivity.

The patterned resin membrane after development may be washed with a rinse liquid.

As the rinse liquid, distilled water, methanol, ethanol, isopropanol, toluene, xylene, propylene glycol monomethyl ether acetate, propylene glycol monomethyl ether or the like may be used singly or in suitable mixture, or these may be used in stepwise combination.

In addition, as an organic material constituting the insulating membranes 102 and 202 other than the cured product of the insulating membrane forming material in the present disclosure, photosensitive resin, a non-conductive film (NCF: Non Conductive Film) which is thermosetting, or a thermosetting resin may be used. The organic material may be used as an underfill material. In addition, the organic material constituting the insulating membranes 102 and 202 may be a heat-resistant resin.

[Processes (c) and (d)]

Process (c) is a process of polishing the first semiconductor substrate 100. In process (c), as shown in FIG. 3(a), the first surface 101a of the first semiconductor substrate 100 is polished using chemical mechanical polishing (CMP) so that the surfaces 103a of the terminal electrodes 103 are at the same level or slightly higher (protruding) than the surface 102a of the insulating membrane 102. In process (c), the first semiconductor substrate 100 may be polished by CMP under conditions that selectively and deeply polish the terminal electrodes 103 made of copper or the like. In process (c), the surfaces 103a of the terminal electrodes 103 may be polished by CMP so that they coincide with the surface 102a of the insulating membrane 102. The polishing method is not limited to CMP, and back grinding or the like may be used. Prior to polishing by CMP, mechanical polishing may be performed using a polishing device such as a surface planer.

In a case in which each surface 103a of the terminal electrode 103 is located slightly higher than the surface 102a of the insulating membrane 102, the difference in height between each surface 103a and the surface 102a may be from 1 nm to 150 nm, or from 1 nm to 15 nm.

Process (d) is a process of polishing the second semiconductor substrate 200. In process (d), as shown in FIG. 3(a), the first surface 201a side, which is one surface of the second semiconductor substrate 200, is polished using the CMP method so that each surface 203a of the terminal electrodes 203 is at the same position or slightly higher (protruding) than the surface 202a of the insulating membrane 202. In process (d), the second semiconductor substrate 200 may be polished by the CMP method under conditions that selectively and deeply polish the terminal electrodes 203 made of copper or the like. In process (d), the surfaces 203a of the terminal electrodes 203 may be polished by CMP so that they coincide with the surface 202a of the insulating membrane 202 . . . . The polishing method is not limited to the CMP method, and back grinding or the like may be used.

In a case in which each surface 203a of the terminal electrode 203 is located slightly higher than the surface 202a of the insulating membrane 202, the difference in height between each surface 203a and the surface 202a may be from 1 nm to 50 nm, or from 1 nm to 15 nm.

In processes (c) and (d), the insulating membrane 102 and the insulating membrane 202 may be polished to have the same thickness, and for example, the insulating membrane 202 may be polished to have a thickness greater than that of the insulating membrane 102. On the other hand, the insulating membrane 202 may be polished to have a thickness smaller than the insulating membrane 102. In a case in which the insulating membrane 202 is thicker than the insulating membrane 102, most of the foreign matter that adheres to the joint interface when dicing the second semiconductor substrate 200 or when mounting a chip may be contained inside the insulating membrane 202, and joint defects may be further reduced. On the other hand, in a case in which the insulating membrane 202 is thicker than the insulating membrane 102, the height of the mounted semiconductor chip 205, that is, the semiconductor device 1, may be reduced. At least one of process (c) or (d) may be performed, and it is preferable to perform both processes (c) and (d).

[Process (e)]

Process (e) is a process of singulating the second semiconductor substrate 200 to obtain plural semiconductor chips 205. In process (e), as shown in FIG. 2(b), the second semiconductor substrate 200 is singulated into plural semiconductor chips 205 by a cutting means such as dicing. In a case in which the second semiconductor substrate 200 is diced, the insulating membrane 202 may be covered with a protective material or the like, and then singulated. In process (e), the insulating membrane 202 of the second semiconductor substrate 200 is divided into insulating membrane portions 202b corresponding to each semiconductor chip 205. Examples of dicing methods for singulating the second semiconductor substrate 200 include plasma dicing, stealth dicing, laser dicing, and the like. As a surface protection material for the second semiconductor substrate 200 during dicing, for example, an organic membrane that can be removed with water, TMAH or the like, or a thin membrane such as a carbon membrane that can be removed with plasma or the like may be provided.

In the above embodiment, after preparing a large-area second semiconductor substrate 200, it is singulated into individual pieces to obtain plural semiconductor chips 205, but the method of preparing the semiconductor chips 205 is not limited to this.

[Process (f)]

Process (f) is a process of aligning the terminal electrodes 203 of each of the plural semiconductor chips 205 with the terminal electrodes 103 of the first semiconductor substrate 100. In process (f), as shown in FIG. 2(c), the semiconductor chips 205 are aligned so that the terminal electrodes 203 of each semiconductor chip 205 face the corresponding terminal electrodes 103 of the first semiconductor substrate 100. For this alignment, an alignment mark or the like may be provided on the first semiconductor substrate 100.

[Process (g)]

Process (g) is a process of bonding the insulating membrane 102 of the first semiconductor substrate 100 and each insulating membrane portions 202b of the plural semiconductor chips 205 to each other. In process (g), after removing an organic matter, a metal oxide matter or the like attached to the surface of each semiconductor chip 205, the semiconductor chips 205 are aligned with the first semiconductor substrate 100 as shown in FIG. 2(c), and then each insulating membrane portions 202b of the plural semiconductor chips 205 is joined to the insulating membrane 102 of the first semiconductor substrate 100 by hybrid bonding (see FIG. 3(b)). At this time, the insulating membrane portions of the semiconductor chips 205 and the insulating membrane 102 of the first semiconductor substrate 100 may be uniformly heated before joining. By joining while heating, the insulating membrane 102 and the insulating membrane portion 202b expand more than the terminal electrodes 103 and 203 due to the difference in thermal expansion coefficient between the insulating membrane 102 and the insulating membrane portion 202b and the terminal electrodes 103 and 203. In process (c), the first semiconductor substrate 100 may be polished so that the height of the insulating membrane 102 is equal to or greater than the height of the terminal electrode 103 due to thermal expansion caused by heating, or in process (d), the second semiconductor substrate 200 may be polished so that the height of the insulating membrane portion 202b is equal to or greater than the height of the terminal electrode 203. A temperature difference between the semiconductor chip 205 and the first semiconductor substrate 100 during joining is preferably within 10° C., for example. By heat joining at such a highly uniform temperature, the insulating membrane 102 and the insulating membrane portion 202b are joined to form an insulating joint portion S1, and the plural semiconductor chips 205 are mechanically and firmly attached to the first semiconductor substrate 100. In addition, since the heat bonding is performed at a highly uniform temperature, positional deviations at the joining points are unlikely to occur, and joining may be performed with high accuracy. At this attachment stage, the terminal electrodes 103 of the first semiconductor substrate 100 and the terminal electrodes 203 of the semiconductor chip 205 are spaced apart from each other, and are not connected (but are aligned). The semiconductor chip 205 may be bonded to the first semiconductor substrate 100 by other bonding methods, such as room temperature bonding.

A thickness of the organic insulating membrane, which is the insulating joint portion where the insulating membrane 102 and the insulating membrane portion 202b are joined, is not particularly limited and may be, for example, 0.1 μm or more, or from the viewpoint of suppressing an influence of foreign matter and device design, may be from 1 μm to 20 μm, and is preferably from 1 μm to 5 μm.

[Process (h)]

Process (h) is a process of joining the terminal electrode 103 of the first semiconductor substrate 100 to the terminal electrodes 203 of each of the plural semiconductor chips 205. In process (h), as shown in FIG. 2(d), after the bonding in process (g) is completed, heat H, pressure, or both are applied to join the terminal electrode 103 of the first semiconductor substrate 100 to each of the terminal electrodes 203 of the semiconductor chips 205 as hybrid bonding (see FIG. 3(c)). In a case in which the terminal electrodes 103 and 203 are made of copper, an annealing temperature in process (g) is preferably from 150° C. to 400° C., and more preferably from 200° C. to 300° C. By such joining process, the terminal electrode 103 and the corresponding terminal electrode 203 are joined to form an electrode joint portion S2, and the terminal electrode 103 and the terminal electrode 203 are mechanically and electrically firmly joined to each other. The electrode joining in process (h) may be performed after the bonding in process (g) or may be performed simultaneously with the bonding in process (g).

As a result of the above, the plural semiconductor chips 205 are electrically and mechanically installed at the predetermined positions with high precision on the first semiconductor substrate 100. For example, a product reliability test (connection test, or the like.) may be performed at the stage of the semi-finished product shown in FIG. 2(d), and only good products may be used in the subsequent processes. Next, an example of a method of producing a semiconductor device using such a semi-finished product will be described with reference to FIG. 4.

[Process (i)]

Process (i) is a process of forming plural pillars 300 between the plural semiconductor chips 205 on a connection surface 100a of the first semiconductor substrate 100. In process (i), as shown in FIG. 4(a), a large number of pillars 300 made of, for example, copper are formed between the plural semiconductor chips 205. The pillars 300 may be formed from copper plating, conductive paste, copper pins, or the like. The pillars 300 are formed so that one end is connected to one of the terminal electrodes of the first semiconductor substrate 100 that is not connected to the terminal electrode 203 of the semiconductor chip 205, and the other end extends upward. The pillar 300 has a diameter of, for example, from 10 μm to 100 μm, and a height of, for example, from 10 μm to 10000 μm. Note that, for example, 1 to 10,000 pillars 300 may be provided between the pair of semiconductor chips 205.

[Process (j)]

Process (j) is a process of molding a resin 301 on the connection surface 100a of the first semiconductor substrate 100 so as to cover the semiconductor chips 205 and the pillars 300. In process (j), as shown in FIG. 4(b), epoxy resin or the like is molded to entirely cover the semiconductor chips 205 and the pillars 300. Examples of a molding method include compression molding, transfer molding, and laminating a film-like epoxy film. By molding the resin, the resin 301 is filled into the spaces between the pillars 300 and between the pillars 300 and the semiconductor chip 205.

This forms a semi-finished product M1 filled with resin. Note that a curing process may be performed after molding the epoxy resin or the like. Also, in a case in which processes (i) and (j) are performed substantially simultaneously, i.e., in a case in which the pillars 300 are formed at the almost same time as the resin molding, the pillars may be formed by an imprinting method, which is a fine transfer method, using a conductive paste or electrolytic plating.

[Process (k)]

Process (k) is a process of grinding and thinning the resin 301 side of the semi-finished product M1, which includes the resin 301 molded in process (j), the plural pillars 300 and the plural semiconductor chips 205, to obtain a semi-finished product M2. In process (k), as shown in FIG. 4(c), an upper side of the semi-finished product M1 is polished with a grinder or the like to thin the resin-molded first semiconductor substrate 100 or the like, thereby obtaining the semi-finished product M2. By the polishing in process (k), thicknesses of the semiconductor chip 205, the pillar 300 and the resin 301 is thinned to, for example, about several tens of μm, the semiconductor chip 205 has a shape corresponding to the second semiconductor chip 20, and the pillar 300 and the resin 301 have a shape corresponding to the pillar portion 30.

### [Process (1)]

Process (1) is a process of forming a wiring layer 400 corresponding to the rewiring layer 40 on the semi-finished product M2 thinned in process (k). In process (1), as shown in FIG. 4(d), a rewiring pattern is formed with polyimide, copper wiring, or the like on the second semiconductor chip 20 and the pillar portion 30 of the ground semi-finished product M2. As a result, a semi-finished product M3 is formed having a wiring structure in which the terminal pitch of the second semiconductor chip 20 and the pillar portion 30 is widened. [Processes (m) and Process (n)]

Process (m) is a process of cutting the semi-finished product M3 on which the wiring layer 400 has been formed in process (1) along the cutting line A to obtain an individual semiconductor devices 1. In process (m), as shown in FIG. 4(d), the semiconductor device substrate is cut along the cutting line A by dicing or the like to obtain an individual semiconductor devices 1. Then, in process (n), the semiconductor device 1a that has been individualized in process (m) is inverted and placed on the substrate 50 and the circuit board 60 to obtain plural semiconductor devices 1 as shown in FIG. 1.

According to the above embodiment, which is an example of a method of producing a semiconductor device, the insulating membrane 102 of the first semiconductor substrate 100 and the insulating membrane 202 of the second semiconductor substrate 200 are cured products of the insulating membrane forming material in the present disclosure. The insulating membrane forming material in the present disclosure has high exposure sensitivity, and suppresses a generation of voids during joining or the like.

Although one embodiment of the method of producing a semiconductor device in the present disclosure has been described in detail above, the present invention is not limited to the above embodiment. For example, in the above embodiment, after the process (i) of forming the pillar 300, the process (j) of molding the resin 301 and the process (k) of grinding and thinning the resin 301 or the like are performed in this order in the process shown in FIG. 4, but it is also possible to first perform the process (j) of molding the resin 301 on the connection surface of the first semiconductor substrate 100, then perform the process (k) of grinding and thinning the resin 301 to a predetermined thickness, and then perform the process (i) of forming the pillar 300. In this case, the work of cutting the pillar 300 may be reduced, and since a portion of the pillar 300 that needs to be cut is not necessary, the material cost can be reduced.

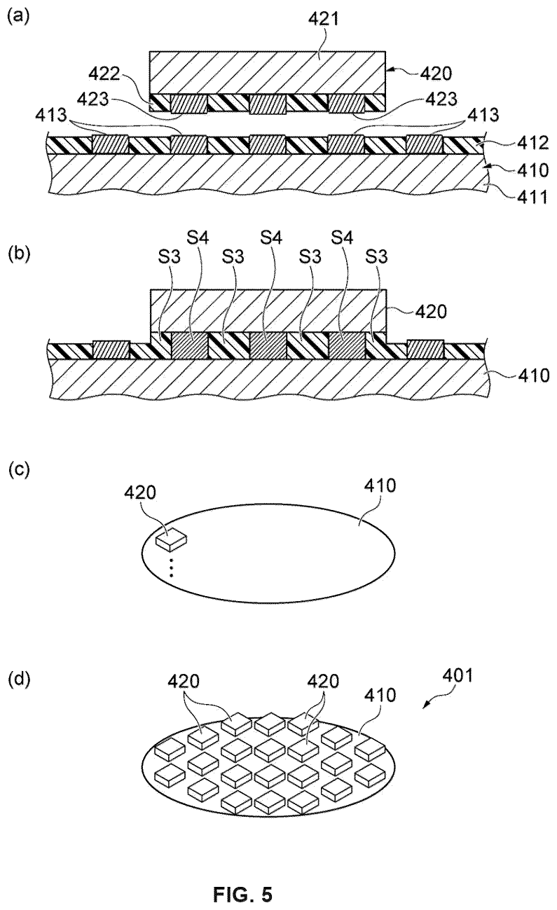

In the above embodiment, an example of C2C bonding has been described, but the present invention may be applied to chip-to-wafer (C2 W) bonding shown in FIG. 5. In C2 W, a semiconductor wafer 410 (first semiconductor substrate), which has a substrate body 411 (first substrate body), and an insulating membrane 412 (first insulating membrane) and plural terminal electrodes 413 (first electrodes) provided on one surface of the substrate body 411, is prepared, and a semiconductor substrate (second semiconductor substrate) before being divided into plural semiconductor chips 420, the semiconductor substrate having a substrate body 421 (second substrate body), and an insulating membrane portion 422 (second insulating membrane) and plural terminal electrodes 423 (second electrodes) provided on one surface of the substrate body 421, is prepared. Then, one surface of the semiconductor wafer 410 and one surface of the second semiconductor substrate before being divided into plural semiconductor chips 420 are polished by CMP or the like, in the same manner as in the above processes (c) and (d). Thereafter, the second semiconductor substrate is subjected to a singulation process similar to process (e) to obtain plural semiconductor chips 420.

Subsequently, as shown in FIG. 5(a), the terminal electrodes 413 of the semiconductor wafer 410 and the terminal electrodes 423 of the semiconductor chip 420 are aligned with each other (process (f)). Then, the insulating membrane 412 of the semiconductor wafer 410 and the insulating membrane portion 422 of the semiconductor chip 420 are bonded to each other (process (g)), and the terminal electrodes 413 of the semiconductor wafer 410 and the terminal electrodes 423 of the semiconductor chip 420 are joined (process (h)), to obtain the semi-finished product shown in FIG. 5(b). As a result, the insulating membrane 412 and the insulating membrane portion 422 are joined to each other to form an insulating joint portion S3, and the semiconductor chip 420 is attached to the semiconductor wafer 410 mechanically and with high precision. In addition, the terminal electrode 413 and the corresponding terminal electrode 423 are joined to each other to form an electrode joint portion S4, and the terminal electrodes 413 and 423 are joined mechanically and electrically.

Then, as shown in (c) and (d) of FIG. 5, plural semiconductor chips 420 are joined to the semiconductor wafer 410, which is a semiconductor wafer, in a similar manner to obtain a semiconductor device 401. Note that the plural semiconductor chips 420 may be joined to the semiconductor wafer 410 one by one by hybrid bonding, or may be bonded collectively to the semiconductor wafer 410 by hybrid bonding.

In such as the method of producing the semiconductor device 401, as in the method of producing the semiconductor device 1 described above, at least one of the insulating membrane 412 of the semiconductor wafer 410 or the insulating membrane portion 422 of the semiconductor chip 420 is an insulating membrane that is a cured product of the insulating membrane forming material in the present disclosure. Therefore, even if foreign matter generated by dicing during the individualization into the semiconductor chips 420 adheres to the insulating membrane, the insulating membrane around the foreign matter easily deforms, and the foreign matter may be contained within the insulating membrane without causing a large void in the insulating membrane. In other words, the insulating membrane may suppress the influence of the foreign matter. Therefore, as in C2C, in the producing method related to C2 W described above, joint defects may be reduced while finely joining the semiconductor wafer 410 and the semiconductor chip 420.

Furthermore, in the above-mentioned method of producing a semiconductor device, an inorganic material may be contained in part of the insulating membrane 102 of the semiconductor substrate 110, in the insulating membrane 202 of the semiconductor chip 205 or the like, within the scope of the effects of the present invention.

The disclosure of Japanese Patent Application No. 2022-050451 is incorporated herein by reference in its entirety.

All documents, patent applications, and technical standards described in this specification are incorporated by reference in this specification to the same extent as if each individual document, patent application, and technical standard was specifically and individually indicated to be incorporated by reference.

### EXAMPLE

The present disclosure will be described in more detail below with reference to examples and comparative examples. Note that the present disclosure is not limited to the following examples.

### (Synthesis Example 1 (Synthesis of A1))

62 g of 3,3′,4,4′-biphenylethertetracarboxylic dianhydride (ODPA), 23 g of 4,4′-diaminodiphenylether (ODA), and 5 g of m-phenylenediamine (MPD) were dissolved in 915 g of 3-methoxy-N,N-dimethylpropanamide. The resulting solution was stirred at 30° C. for 2 hours to obtain polyamic acid. 78 g of trifluoroacetic anhydride and 109 g of 2-hydroxyethyl methacrylate (HEMA) were added thereto at room temperature (25° C.) and stirred at 45° C. for 10 hours. The reacted solution was dropped into distilled water, and a precipitate was collected by filtration and dried under reduced pressure to obtain polyimide precursor A1.

A weight-average molecular weight of A1 was determined using gel permeation chromatography (GPC) in terms of standard polystyrene. The weight-average molecular weight of A1 was 22,000. Specifically, the weight-average molecular weight was measured under the following conditions using a solution in which 0.5 mg of A1 was dissolved in 1 mL of a solvent which is tetrahydrofuran (THF)/dimethylformamide (DMF)=1/1 (volume ratio).

### (Measurement Conditions)

Measuring device: Shimadzu Corporation SPD-M20A
Pump: Shimadzu Corporation LC-20AD
Column oven: Shimadzu Corporation: CTO-20A
Measurement conditions: Column Gelpack GL-S300MDT-5×2
Eluent: THF/DMF=1/1 (volume ratio)
   LiBr (0.03 mol/L), H₃PO4 (0.06 mol/L)
Flow rate: 1.0 mL/min, Detector: UV 270 nm, Column Ram temperature: 40° C.
Standard polystyrene: TSKgel standard Polystyrene Type F-1, F-4, F-20, F-80 manufactured by Tosoh Corporation, and create a calibration curve using A-2500

### <Esterification Rate>

An esterification rate of A1 (a ratio of ester groups reacted with HEMA with respect to a total of ester groups reacted with HEMA and carboxy groups unreacted with HEMA) was calculated by performing NMR measurements under the following conditions. The esterification rate was 78 mol %, and a rate of unreacted carboxy groups was 22 mol %.

### (Measurement Conditions)

Measuring equipment: AV400M manufactured by Bruker Biospin
Magnetic field strength: 400 MHz
Reference material: Tetramethylsilane (TMS)
Solvent: Dimethylsulfoxide (DMSO)

### (Synthesis Example 2 (Synthesis of A2))

The same procedure as in Synthesis Example 1 was carried out, except that 23 g of 4,4′-diaminodiphenyl ether (ODA) and 5 g of m-phenylenediamine (MPD) were replaced with 51 g of 1,3-bis(3-aminophenoxy)benzene (APB-1,3,3) to obtain polyimide precursor A2. A weight average molecular weight of A2 was 25,000.

An esterification rate of A2 was calculated by performing NMR measurement under the above-mentioned conditions. The esterification rate was 75 mol %, and a rate of unreacted carboxyl groups was 25 mol %.

### (Synthesis Example 3 (Synthesis of A3))

The same procedure as in Synthesis Example 2 was carried out, except that the ODPA in Synthesis Example 2 was replaced with 104 g of 4,4′-(4,4′-isopropylidenediphenoxy)diphthalic anhydride (BPADA), to obtain polyimide precursor A3. A weight-average molecular weight of A3 was 25,000.

An esterification rate of A4 was calculated by performing NMR measurement under the above-mentioned conditions. The esterification rate was 78 mol %, and a rate of unreacted carboxyl groups was 22 mol %.

### (Synthesis Example 4 (Synthesis of A4))

The same procedure as in Synthesis Example 1 was carried out, except that 23 g of 4,4′-diaminodiphenyl ether (ODA) and 5 g of m-phenylenediamine (MPD) were replaced with 36 g of 2,2′-dimethylbiphenyl-4,4′-diamine (DMAP) to obtain polyimide precursor A4. A weight average molecular weight of A4 was 25,000.

An esterification rate of A4 was calculated by performing NMR measurement under the above-mentioned conditions. The esterification rate was 74 mol %, and a rate of unreacted carboxyl groups was 26 mol %.

### Examples 1 to 14, Comparative Examples 1 to 2

### (Preparation of Insulating Membrane Forming Material)

The insulating membrane forming materials of Examples 1 to 14 and Comparative Examples 1 to 2 were prepared as follows, using the components and amounts shown in Table 1. The units of the amounts of each component in Table 1 are parts by mass. Blank in Table 1 means that the corresponding component was not blended. In each of the Examples and Comparative Examples, a mixture of each component was kneaded overnight at room temperature (25° C.) in a general solvent-resistant container, and then pressure filtered using a filter with a 0.2 μm pore size. The following evaluations were performed using the obtained insulating membrane forming materials.

Components in Table 1 are as follows.
(A) component: polyimide precursor
A1 to A4 as above
(B) component: Solvent
B1: 3-methoxy-N,N-dimethylpropanamide
B2: y-butyrolactone
(C) component: Photopolymerization initiator
C1: 1-phenyl-1,2-propanedione-2-(O-ethoxycarbonyl) oxime
C2: 1-[4-(phenylthio)phenyl]octane-1,2-dione=2-(O-benzoyloxy) oxime)
C3: O-acetyl-1-[6-(2-methylbenzoyl)-9-ethyl-9H-carbazol-3-yl]ethanone oxime
C4: 1-[4-(4-hydroxyethyloxy-phenylthio)phenyl]-1,2-propanedione-2-(O-acetyl oxime)
C5: 2-hydroxy-2-methylpropiophenone (IRGACURE 1173)
C6: 4′-(methylthio)-a-morpholino-a-methylpropiophenone (Irgacure 907)
(D) component: Sensitizer
D1: 4,4′-bis(diethylamino)benzophenone (EMK)
(E) Component: Polymerizable monomer
E1: Triethylene glycol dimethacrylate (TEGDMA)
(G) component: Polymerization inhibitor
G1: 1,4,4-trimethyl-2,3-diazabicyclo [3.2.2]nona-2-ene-2,3-dioxide
(H) Component: Coupling agent
H1: 50% by mass solution of 3-ureidopropyltriethoxysilane in methanol

### (Evaluation of the Presence or Absence of Voids)

The insulating membrane forming materials of Examples 1 to 14 and Comparative Examples 1 and 2 were spin-coated on an 8-inch Si wafer using a spin coater coating device, and then heated and dried at 100° C. for 240 seconds to form resin membranes. A mask capable of producing a circular resin membrane with a diameter of 180 mm was placed on the obtained resin membrane, and light with a wavelength of 365 nm (i-line) was irradiated for a predetermined exposure amount. After that, it was developed for a predetermined time with cyclopentanone, or TMAH of 2.38% by volume. The obtained patterned resin membranes were cured in a nitrogen atmosphere at 200° C. for 2 hours using a vertical diffusion furnace μ-TF, and 10 mm from the outer periphery of the resin membranes on the Si wafers were removed to produce patterned resin membranes.

The obtained cured membranes were polished by CMP to obtain polished cured membranes with a surface roughness Ra of from 0.5 nm to 3 nm within 10 μm² as measured by AFM (atomic force microscope). The polished cured membranes were scrubbed with a general cleaning solution, and then a part of each scrubbed cured membranes was cut into 5 mm square pieces using a blade dicer (DISCO Corporation, DFD-6362) to obtain chips with resin.

The obtained chips with resin were pressed against the polished cured membranes by a flip chip bonder at a predetermined pressure and 250° C. for 15 seconds to produce cured membranes with chip. For each insulating membrane forming material, five chips pressed against the polished cured membrane were evaluated as described below.

The obtained cured membranes with chip were observed for the presence or absence of voids indicating poor adhesion at the insulating membrane interface using SAT (scanning acoustic tomography). The evaluation criteria for voids are as follows. The results are shown in Table 1. In a case in which the evaluation is A, the occurrence of voids is suppressed and the evaluation is judged to be good.

### Evaluation Criteria for Void

A: Voids were observed in two or less chips out of five chips.
B: Voids were observed in more than two chips out of five chips.
C: One or more chips peeled off when measuring the SAT.

### (Evaluation of Sensitivity)

The insulating membrane forming materials was spin-coated on a Si substrate and heated and dried on a hot plate at 100° C. for 240 seconds to form a resin membrane with a thickness of approximately 12 μm after application. The resin membrane was exposed to i-rays of from 100 to 1100 mJ/cm² in 100 mJ/cm² increments in a specified pattern using an i-ray stepper NES2WA06 (manufactured by Nikon Corporation) through a photomask. The exposed resin membrane was then developed with cyclopentanone for 20 seconds using a coater developer ACT8 (manufactured by Tokyo Electron Ltd.). The minimum exposure dose at which a thickness of the resin membrane in the exposed area became 70% or more of an initial thickness was taken as the sensitivity.

The evaluation criteria for sensitivity are as follows. The results are shown in Table 1. In a case in which the evaluation is A, the sensitivity is high and it is judged to be good.

### Evaluation Criteria for Sensitivity

A: Sensitivity is 300 mJ/cm² or less
B: Sensitivity is greater than 300 mJ/cm² and 500 mJ/cm² or less
C: Sensitivity is greater than 500 mJ/cm2

### (Evaluation of Pattern Profile (PP))

An area exposed to 600 mJ/cm² in the above sensitivity evaluation was cut out with a diamond pen, and the cross section of the 100 μm line pattern was observed with a scanning electron microscope (SEM), and the pattern profile was evaluated based on the shape of the pattern cross section.

The evaluation criteria for pattern profile are as follows. The results are shown in Table 1. In a case in which the evaluation is A, the pattern profile is excellent and is evaluated as good.

### Evaluation Criteria for Pattern Profile (PP)

A: An intersection of a top surface and a side surface is clear in the cross-sectional shape, and there are no abnormalities such as protrusions at the intersection.
B: A taper shape of the side surface is lost in the cross-sectional shape, and the intersection of the top surface and the side surface is not clear.
C: An abnormality such as a protrusion exists at the intersection of the top surface and the side surface in the cross-sectional shape.

### (Evaluation of Low-Temperature Joint)

A patterned resin membrane and chips with resin were prepared in the same manner as in the evaluation of void generation described above, and the chip with resin was placed on the patterned resin membrane and covered with a carbon sheet for reducing unevenness. Using a bonding device (manufactured by EVG), pressure bonding was performed under atmospheric conditions at 180° C. for 180 seconds, with a load of 100n applied to a 1 cm-sized pressure area. Pressure bonding was performed on three chips, and whether the chips would come off even if a small external force was applied to the bonded chips was used as an index of low-temperature joint.

The evaluation criteria for low-temperature joint are as follows. The results are shown in Table 1. In a case in which the evaluation is A, the low-temperature joint is excellent and the evaluation is judged to be good.

### Evaluation Criteria for Low-Temperature Joint

A: Adhesion was observed in all of the three chips.
B: Adhesion was observed in one or two of the three chips.
C: Adhesion was not observed in any of the three chips.

TABLE 1

| | | | | | | | | | | | | | | Comparative | |
|---|---|---|---|---|---|---|---|---|---|---|---|---|---|---|---|
| | Example | | | | | | | | | | | | | Example | |
| material | 1 | 2 | 3 | 4 | 5 | 6 | 8 | 9 | 10 | 11 | 12 | 13 | 14 | 1 | 2 |
| A1 | 100 | | | | | | | | | | | | | | |
| A2 | | 100 | 100 | 100 | 100 | 100 | 100 | 100 | 100 | 100 | 100 | | | 100 | 100 |
| A3 | | | | | | | | | | | | 100 | | | |
| A4 | | | | | | | | | | | | | 100 | | |
| B1 | 150 | 150 | 150 | 150 | 150 | 150 | 150 | 150 | 150 | | | 150 | 150 | 150 | 150 |
| B2 | | | | | | | | | | 150 | 150 | | | | |
| C1 | 10 | 5 | 10 | 10 | | 10 | | 10 | | 10 | 10 | 10 | 10 | | |
| C2 | | | | 0.5 | 2 | | | | | | | | | | |
| C3 | | | | | | 0.5 | 2 | | | | 0.5 | | | | |
| C4 | | | | | | | | 0.5 | 2 | | | | | | |
| C5 | | | | | | | | | | | | | | 10 | |
| C6 | | | | | | | | | | | | | | | 10 |
| D1 | 0.5 | 0.5 | 0.5 | 0.5 | 0.5 | 0.5 | 0.5 | 0.5 | 0.5 | 0.5 | 0.5 | 0.5 | 0.5 | 0.5 | 0.5 |
| E1 | 20 | 20 | 20 | 20 | 20 | 20 | 20 | 20 | 20 | 20 | 20 | 20 | 20 | 20 | 20 |
| G1 | 0.5 | 0.5 | 0.5 | 0.5 | 0.5 | 0.5 | 0.5 | 0.5 | 0.5 | 0.5 | 0.5 | 0.5 | 0.5 | 0.5 | 0.5 |
| H1 | 3 | 3 | 3 | 3 | 3 | 3 | 3 | 3 | 3 | 3 | 3 | 3 | 3 | 3 | 3 |
| Void | A | A | A | A | A | A | A | A | A | A | A | A | A | C | C |
| Sensitivity | A | B | A | A | A | A | A | A | A | A | A | A | A | C | C |
| PP | A | A | A | A | B | A | B | A | B | A | A | A | A | C | C |
| Low-temperature | B | A | A | A | A | A | A | A | A | A | A | A | B | A | A |
| joint | | | | | | | | | | | | | | | |

As shown in Table 1, Examples 1 to 14 were superior in exposure sensitivity compared to Comparative Examples 1 and 2, and the generation of voids at the insulating membrane interface was suppressed. Among the Examples, Examples 1 to 4, 6, 9, and 11 to 14, which used C1 as a photopolymerization initiator, were superior in pattern profile. Moreover, Examples 4, 6, 9, and 12, which used C1 and any of C2 to C4 as a photopolymerization initiator in combination, were superior in exposure sensitivity while maintaining the pattern profile.

Whereas, Comparative Examples 1 and 2 had more voids generated at the joint interface than the Examples, and the sensitivity was also lower. Comparative Examples 1 and 2 also had a worse pattern profile than the Examples.

### (Measurement of Glass Transition Temperature (Tg) of Cured Membrane)

Cured membranes were formed as follows using the insulating membrane forming materials of Examples 1, 13, and 14 and Comparative Example 1, and then the glass transition temperatures were measured. The photosensitive insulating membrane forming material was spin-coated on a Si substrate and dried by heating on a hot plate at 100° C. for 240 seconds to form a photosensitive resin membrane with a thickness of approximately 10 μm after curing.

The obtained photosensitive resin membrane was broadband (BB) exposed to an exposure dose of 800 mJ/cm² using a mask aligner MA-8 (manufactured by SUSS MicroTec). The exposed resin membrane was developed with cyclopentanone for 20 seconds using a coater developer ACT8 (manufactured by Tokyo Electron Ltd.) to obtain a strip-shaped patterned resin membrane with a width of 10 mm.

The obtained patterned resin membrane was cured in a vertical diffusion furnace u-TF at 200° C. for 2 hours under a nitrogen atmosphere to obtain a patterned cured product with a thickness of 10 μm. The obtained patterned cured product was immersed in a 4.9% by mass aqueous solution of hydrofluoric acid to peel off the 10 mm wide patterned cured product from the Si substrate.

Using RSA-G2 manufactured by TA Instruments, a storage modulus and loss modulus of the pattern cured material peeled off from the Si substrate were measured under the following conditions: test frequency 1 Hz, heating rate 5° C./min, measurement mode: tension, in N₂ atmosphere, measurement range from −50° C. to 400° C., chuck distance 10 mm, sample width 2.0 mm. A loss tangent was calculated from the obtained storage modulus and loss modulus, and a peak of the loss tangent was taken as the Tg (glass transition temperature).

A Tg of Example 1 was 210° C., a Tg of Example 13 was 160° C., a Tg of Example 14 was 220° C., and a Tg of Comparative Example 1 was 170° C.

### EXPLANATION OF REFERENCES

1, 1a, 401 . . . semiconductor device, 10 . . . first semiconductor chip, 20 . . . second semiconductor chip, 30 . . . pillar portion, 40 . . . rewiring layer, 50 . . . substrate, 60 . . . circuit board, 61 . . . terminal electrode, 100 . . . first semiconductor substrate, 101 . . . first substrate body, 101a . . . first surface, 102 . . . insulating membrane (first insulating membrane), 103 . . . terminal electrode (first electrode), 103a . . . surface, 200 . . . second semiconductor substrate, 201 . . . second substrate body, 201a . . . first surface, 202 . . . insulating membrane (second insulating membrane), 203 . . . terminal electrode (second electrode), 203a . . . surface, 205 . . . semiconductor chip, 300 . . . pillar, 301 . . . resin, 410 . . . semiconductor wafer (first semiconductor substrate), 411 . . . substrate body (first substrate body), 412 . . . insulating membrane (first insulating membrane), 413 . . . terminal electrode (first electrode), 420 . . . semiconductor chip (second semiconductor substrate), 421 . . . substrate body (second substrate body), 422 . . . insulating membrane portion (second insulating membrane), 423 . . . terminal electrode (second electrode), A . . . cutting line, H . . . heat, M1 to M3 . . . semi-finished product, S1 . . . insulating joint portion, S2 . . . electrode joint portion, S3 . . . insulating joint portion, S4 . . . electrode joint portion

1. A hybrid bonding insulating membrane forming material comprising a (A) polyimide precursor having a polymerizable unsaturated bonding site, a (B) solvent, and a (C) oxime-based photopolymerization initiator.

2. The hybrid bonding insulating membrane forming material according to claim 1, wherein the (C) oxime-based photopolymerization initiator comprises a compound represented by the following Formula (I): 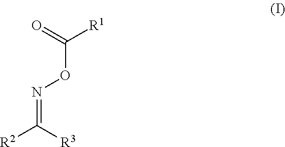
wherein, in Formula (I), R¹ represents an alkyl group, an alkoxy group, a phenyl group, or a phenoxy group, R² represents an alkyl group, and R³ represents a carbonyl group or a monovalent organic group linked by a single bond.

3. The hybrid bonding insulating membrane forming material according to claim 2, wherein the (C) oxime-based photopolymerization initiator includes a compound in which R¹ in Formula (I) is represented by an alkoxy group.

4. The hybrid bonding insulating membrane forming material according to claim 2, wherein the (C) oxime-based photopolymerization initiator includes a compound A in which R¹ in Formula (I) is represented by an alkoxy group, and a compound B in which R¹ in Formula (I) is represented by an alkyl group or a phenyl group.

5. The hybrid bonding insulating membrane forming material according to claim 1, wherein the (A) polyimide precursor includes a compound having a structural unit represented by the following Formula (1): 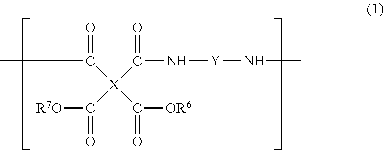
wherein, in Formula (1), X represents a tetravalent organic group, Y represents a divalent organic group, and each of R⁶ and R⁷ independently represents a hydrogen atom or a monovalent organic group, and at least one of R⁶ or R⁷ has a polymerizable unsaturated bond.

6. The hybrid bonding insulating membrane forming material according to claim 5, wherein the tetravalent organic group represented by X in Formula (1) is a group represented by the following Formula (E): 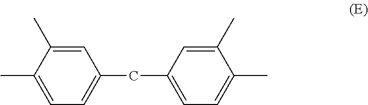
wherein, in Formula (E), C represents a single bond, an alkylene group, a halogenated alkylene group, a carbonyl group, a sulfonyl group, an ether bond (—O—), a sulfide bond (—S—), a phenylene group, an ester bond (—O—C(═O)—), a silylene bond (—Si(R^{A})₂—) wherein each of the two R^{A}s independently represents a hydrogen atom, an alkyl group, or a phenyl group), a siloxane bond (—O—(Si(R^{B})₂—O—)ₙ) wherein each of the two R^{B}s independently represents a hydrogen atom, an alkyl group, or a phenyl group, and n represents an integer of 1 or more), or a divalent group combining at least two of these.

7. The hybrid bonding insulating membrane forming material according to claim 5, wherein the divalent organic group represented by Y in Formula 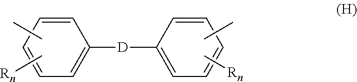
wherein, in Formula (H), each R independently represents an alkyl group, an alkoxy group, a halogenated alkyl group, a phenyl group, or a halogen atom, and each n independently represents an integer from 0 to 4. D represents a single bond, an alkylene group, a halogenated alkylene group, a carbonyl group, a sulfonyl group, an ether bond (—O—), a sulfide bond (—S—), a phenylene group, an ester bond (—O—C(═O)—), a silylene bond (—Si(R^{A})₂—) wherein each of two RAs independently represents a hydrogen atom, an alkyl group, or a phenyl group), a siloxane bond (—O—(Si(R^{B})₂—O—)ₙ) wherein each of two R^{B}s independently represents a hydrogen atom, an alkyl group, or a phenyl group, and n represents an integer of 1 or more), or a divalent group combining at least two of these.

8. The hybrid bonding insulating membrane forming material according to claim 7, wherein D in Formula (H) comprises an ether bond (—O—).

9. The hybrid bonding insulating membrane forming material according to claim 5, wherein the monovalent organic group represented by R⁶ and R⁷ in Formula (1) is a group represented by the following Formula (2), an ethyl group, an isobutyl group or a t-butyl group, and at least one of R⁶ or R⁷ is the group represented by Formula (2): 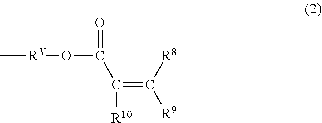
wherein, in Formula (2), each of R⁸ to R₁₀ independently represents a hydrogen atom or an aliphatic hydrocarbon group having 1 to 3 carbon atoms, and R^{x} represents a divalent linking group.

10. The hybrid bonding insulating membrane forming material according to claim 1, further comprising (D) a sensitizer.

11. The hybrid bonding insulating membrane forming material according to claim 1, further comprising (E) a polymerizable monomer.

12. The hybrid bonding insulating membrane forming material according to claim 1, which has a glass transition temperature of from 50° C. to 300° C. in a case in which a cured product is formed.

13. A method of producing a semiconductor device, the method comprising:
preparing a first semiconductor substrate having a first substrate body, and a first electrode and a first organic insulating membrane provided on one surface of the first substrate body;
preparing a semiconductor chip having a semiconductor chip substrate body, and a second organic insulating membrane and a second electrode provided on one surface of the semiconductor chip substrate body; and
joining the first electrode to the second electrode, and bonding the first organic insulating membrane to the second organic insulating membrane,
wherein the hybrid bonding insulating membrane forming material according to claim 1 is used in production of at least one of the first organic insulating membrane or the second organic insulating membrane.

14. The method of producing a semiconductor device according to claim 13, wherein joining the first electrode to the second electrode is performed after bonding the first organic insulating membrane to the second organic insulating membrane.

15. The method of producing a semiconductor device according to claim 13, further comprising:
polishing at least one of the one surface of the first semiconductor substrate or the one surface of the semiconductor chip before the first electrode is joined to the second electrode and before the first organic insulating membrane is bonded to the second organic insulating membrane.

16. The method of producing a semiconductor device according to claim 15, wherein the polishing comprises chemical mechanical polishing.

17. The method of producing a semiconductor device according to claim 16, wherein the polishing further comprises mechanical polishing.

18. The method of producing a semiconductor device according to claim 13, wherein, in the joining between the first electrode and the second electrode, at least one of the following is satisfied: a thickness of the first organic insulating film is greater than a thickness of the first electrode; or a thickness of the second organic insulating film is greater than a thickness of the second electrode.

19. A semiconductor device comprising:
a first semiconductor substrate having a first substrate body, and a first organic insulating membrane and a first electrode provided on one surface of the first substrate body; and
a semiconductor chip having a semiconductor chip substrate body, and a second organic insulating membrane and a second electrode provided on one surface of the semiconductor chip substrate body,
wherein the first organic insulating membrane and the second organic insulating membrane are joined to each other, and the first electrode and the second electrode are joined to each other, and
at least one of the first organic insulating membrane or the second organic insulating membrane is a cured product of the hybrid bonding insulating membrane forming material according to claim 1.
